(19) United States
(12) Patent Application Publication
(10) Pub. No.: US 2026/0032353 A1
(43) Pub. Date: Jan. 29, 2026

(54) IMAGE SENSORS WITH SINUSOIDAL RESET, NOISE CANCELLATION, AND NONPULSED CHARGE TRANSFER FOR INSPECTION AND METROLOGY

(71) Applicant: KLA Corporation, Milpitas, CA (US)

(72) Inventors: Yung-Ho Alex Chuang, Cupertino, CA (US); Devis Contarato, San Carlos, CA (US); John Fielden, Los Altos, CA (US)

(21) Appl. No.: 19/274,265

(22) Filed: Jul. 18, 2025

Related U.S. Application Data
(60) Provisional application No. 63/674,275, filed on Jul. 23, 2024.
(60) Provisional application No. 63/757,307, filed on Feb. 11, 2025.

(51) Int. Cl. H04N 25/60; H04N 25/711; H04N 25/768; H04N 25/773; H10F 39/00

(52) U.S. Cl. CPC H04N 25/60; H04N 25/711; H04N 25/768; H04N 25/773; H10F 39/806

(57) ABSTRACT

An image sensor is disclosed. The image sensor may include a plurality of sensing nodes electrically connected to at least one circuit of the circuits, the sensing nodes formed on the first side of a silicon layer adjacent to the circuits. Each sensing node may include a floating diffusion structure connected to one of at least one channel of the circuits and an output circuit. Each sensing node may include a charge reset structure configured to remove a charge from the floating diffusion structure. Each sensing node may include a noise-cancellation gate electrode adjacent to the floating diffusion structure and configured to be driven by a noise-cancellation signal. The image sensor may include a resistive gate electrode configured for at least one of direct current or non-pulsed signals. A charge reset structure of each sensing node may be driven with a voltage following a sinusoidal waveform.

### CROSS REFERENCE TO RELATED APPLICATIONS

The present application claims the benefit of U.S. Provisional Application Ser. No. 63/674,275, filed Jul. 23, 2024; and U.S. Provisional Application Ser. No. 63/757,307, filed Feb. 11, 2025, all of which are incorporated herein by reference in their entirety

### TECHNICAL FIELD

The present disclosure generally relates to image sensors and associated electronic circuits suitable for sensing radiation at visible, UV, deep UV (DUV), vacuum UV (VUV), extreme UV (EUV), and X-ray wavelengths, and for sensing electrons or other charged particles, and to methods for operating such image sensors. The sensors and circuits are particularly suitable for use in charge-coupled devices (CCDs) for application in inspection and metrology systems, including those used to inspect photomasks, reticles, semiconductor wafers, substrates for supporting and/or interconnecting semiconductors, and printed circuit boards (PCBs). The sensors and circuits can also be adapted for use in image sensors fabricated using Complementary Metal Oxide-Semiconductor (CMOS) manufacturing processes.

### BACKGROUND

The semiconductor and integrated circuit industry requires a large number of fabrication processes to form various features and multiple levels of the semiconductor devices. Examples of such fabrication processes include, but are not limited to, lithography, chemical-mechanical polishing (CMP), etch, deposition, and ion implantation. These fabrication processes require inspection tools providing increasingly higher sensitivity to detect smaller defects and particles, while maintaining high throughput for a lower cost of ownership. The semiconductor industry is currently manufacturing semiconductor devices with feature dimensions around 20 nanometers (nm) and smaller. Within a few years, the industry will be manufacturing devices with feature dimensions around 5 nm. Particles and defects just a few nm in size can reduce wafer yields and must be captured with high accuracy to ensure high production yield, while doing so in a time and cost-effective way. In the future, the possible transition from today's 300 mm wafers to 450 mm wafers will also require increased inspection speed to maintain high throughput. Thus, the semiconductor industry is driven by ever greater demand for inspection tools that can achieve high sensitivity at high speed.

An image sensor is a key component of a semiconductor inspection tool and plays a critical role in determining defect detection sensitivity and inspection speed. In order to detect small defects or particles on photomasks, reticles, and semiconductor wafers, image sensors need to have good signal-to-noise ratio (SNR). Increasing the intensity of the light used to illuminate the article being inspected can also increase the sensor signal relative to the noise. However, high power densities from the illumination are expensive to generate, can degrade the optics of the inspection system, and may damage the article being inspected. Therefore, sensors with low noise that can operate at high speed are required.

Considering their image quality, light sensitivity, and readout noise performance, charge-coupled devices (CCDs) are widely used as image sensors for semiconductor inspection applications. CCDs are especially suited to be configured to function as a time-delay integration (TDI) sensor, due to their ability to move and integrate the signal charge, generated in the CCD sensors in response to light collected from the sample being inspected, in synchrony with the motion of the stage on which the sample is held.

Sources of noise in an image sensor include dark current within the sensor, readout noise in the sensor output signal(s), noise in the electronics that amplifies and digitizes the sensor output signal(s), and noise from external electronics, including drivers and controllers, that gets coupled into the sensor output signal.

Therefore, a need arises for an image sensor capable of detecting low light levels at high speed with high signal-to-noise ratio to overcome the above disadvantages.

### SUMMARY

An image sensor is disclosed in accordance with one or more illustrative embodiments of the present disclosure. In one illustrative embodiment the image sensor may include a silicon layer configured to generate electron-hole pairs based on light being incident on a light-sensitive area of the silicon layer. In one illustrative embodiment the image sensor may include a plurality of circuits formed on a first side of the silicon layer. In one illustrative embodiment the circuits may include at least one channel and first gate electrodes configured to control electron accumulation in the at least one channel in response to generation of the electron-hole pairs. In one illustrative embodiment the image sensor may include a plurality of sensing nodes electrically connected to at least one circuit of the circuits, the sensing nodes formed on the first side of the silicon layer adjacent to the circuits. In one illustrative embodiment each sensing node may include a floating diffusion structure connected to one of the at least one channel of the circuits and an output circuit of the image sensor. In one illustrative embodiment each sensing node may include a charge reset structure configured to remove a charge from the floating diffusion structure. In one illustrative embodiment the floating diffusion structure may be configured to convert the charge responsive to the electron accumulation to a voltage proportional to an amount of the charge and dependent on a capacitance of the floating diffusion structure. In one illustrative embodiment the output circuit may be configured to generate output responsive to the voltage output by the floating diffusion structure. In one illustrative embodiment each sensing node may include a noise-cancellation gate electrode adjacent to the floating diffusion structure and configured to be driven by a noise-cancellation signal.

In one illustrative embodiment the circuits may be configured as charge-coupled device (CCD) circuits.

In one illustrative embodiment the circuits may be configured as complementary metal-oxide-semiconductor (CMOS) circuits.

In one illustrative embodiment the image sensor may be configured as a backside illuminated charge-coupled device (CCD) sensor.

In one illustrative embodiment the image sensor may be configured as a backside illuminated complementary metal-oxide-semiconductor (CMOS) sensor.

In one illustrative embodiment the image sensor may be configured to function as a time-delay integration (TDI) sensor.

In one illustrative embodiment the image sensor may be configured to function as an avalanche image sensor.

In one illustrative embodiment the silicon layer may be a silicon epitaxial layer.

In one illustrative embodiment the silicon layer may be a silicon epitaxial layer comprising intrinsic or p-type doped silicon with a dopant concentration less than 10¹⁴ cm⁻³.

In one illustrative embodiment the at least one channel may include an n-type doped buried channel.

In one illustrative embodiment the image sensor may further include a thin p-type layer with a dopant concentration at least ten times higher than a dopant concentration of the silicon layer, the thin p-type layer disposed on a second side of the silicon layer opposite to the first side.

In one illustrative embodiment the image sensor may further include an antireflection layer disposed on a second side of the silicon layer opposite to the first side.

In one illustrative embodiment the circuits may be configured as a linear array of pixels.

In one illustrative embodiment the circuits may be configured as a two-dimensional array of pixels.

In one illustrative embodiment each pixel may include one or more circuits comprising the one of the at least one channel connected to the floating diffusion structure and the floating diffusion structure may be configured for charge-to-voltage conversion.

A system is disclosed in accordance with one or more illustrative embodiments of the present disclosure. In one illustrative embodiment the system may include an illumination subsystem configured for directing light generated by an illumination source to the sample. In one illustrative embodiment the system may include an image sensor positioned in a path of light from the sample. In one illustrative embodiment the image sensor may include a silicon layer configured to generate electron-hole pairs based on the light from the sample being incident on a light-sensitive area of the silicon layer. In one illustrative embodiment the image sensor may include a plurality of circuits formed on a first side of the silicon layer. In one illustrative embodiment the circuits may include at least one channel and first gate electrodes configured to control electron accumulation in the at least one channel in response to generation of the electron-hole pairs. In one illustrative embodiment the image sensor may include a plurality of sensing nodes electrically connected to at least one circuit of the circuits, the sensing nodes formed on the first side of the silicon layer adjacent to the circuits. In one illustrative embodiment each sensing node may include a floating diffusion structure connected to one of the at least one channel of the circuits and an output circuit of the image sensor. In one illustrative embodiment each sensing node may include a charge reset structure configured to remove a charge from the floating diffusion structure. In one illustrative embodiment the floating diffusion structure may be configured to convert the charge responsive to the electron accumulation to a voltage proportional to an amount of the charge and dependent on a capacitance of the floating diffusion structure. In one illustrative embodiment the output circuit may be configured to generate output responsive to the voltage output by the floating diffusion structure. In one illustrative embodiment each sensing node may include a noise-cancellation gate electrode adjacent to the floating diffusion structure and configured to be driven by a noise-cancellation signal. In one illustrative embodiment the image sensor may include a circuit configured to drive the noise-cancellation gate electrode with the noise-cancellation signal. In one illustrative embodiment the system may include a controller configured for determining the information for the sample based on the output.

In one illustrative embodiment the system may be configured as an inspection system and the information for the sample may include information for defects detected on the sample based on the output.

A method is disclosed in accordance with one or more illustrative embodiments of the present disclosure. In one illustrative embodiment the method may include directing and focusing light onto the sample. In one illustrative embodiment the method may include receiving light from the sample and directing the light to an image sensor. In one illustrative embodiment the image sensor may include a silicon layer configured to generate electron-hole pairs based on the light from the sample being incident on a light-sensitive area of the silicon layer. In one illustrative embodiment the image sensor may include a plurality of circuits formed on a first side of the silicon layer. In one illustrative embodiment the circuits may include at least one channel and first gate electrodes configured to control electron accumulation in the at least one channel in response to generation of the electron-hole pairs. In one illustrative embodiment the image sensor may include a plurality of sensing nodes electrically connected to at least one circuit of the circuits, the sensing nodes formed on the first side of the silicon layer adjacent to the circuits. In one illustrative embodiment each sensing node may include a floating diffusion structure connected to one of the at least one channel of the circuits and an output circuit of the image sensor. In one illustrative embodiment each sensing node may include a charge reset structure configured to remove a charge from the floating diffusion structure. In one illustrative embodiment the floating diffusion structure may be configured to convert the charge responsive to the electron accumulation to a voltage proportional to an amount of the charge and dependent on a capacitance of the floating diffusion structure. In one illustrative embodiment the output circuit may be configured to generate output responsive to the voltage output by the floating diffusion structure. In one illustrative embodiment each sensing node may include a noise-cancellation gate electrode adjacent to the floating diffusion structure and configured to be driven by a noise-cancellation signal. In one illustrative embodiment the method may include moving the sample relative to the light simultaneously with receiving the light. In one illustrative embodiment the method may include driving the first gate electrodes with charge transfer clock signals synchronized to the moving of the sample relative to the light, the charge transfer clock signals causing the electron accumulation to be transferred from the first gate electrodes to the sensing nodes. In one illustrative embodiment the method may include driving the charge reset structure of each sensing node with a reset clock signal that causes the electron accumulation to be removed from the floating diffusion structure of each sensing node. In one illustrative embodiment the method may include driving the noise-cancellation gate electrode of each sensing node with the noise-cancellation signal. In one illustrative embodiment the method may include utilizing a readout circuit including an analog-to-digital converter (ADC) coupled to the output circuit electrically connected to the floating diffusion structure of each sensing node and configured to convert the voltage output by each sensing node to a digital number.

In one illustrative embodiment the method may include driving the first gate electrodes with voltages following a sinusoidal waveform over time.

In one illustrative embodiment the method may include driving the charge reset structure of each sensing node with a voltage following a sinusoidal waveform over time.

In one illustrative embodiment the noise-cancellation signal may include a voltage following a waveform over time to cancel feedthrough on the voltage output by each sensing node caused by one or more couplings, the one or more couplings including a capacitive coupling of the charge transfer clock signals and the reset clock signal with each sensing node.

A system is disclosed in accordance with one or more illustrative embodiments of the present disclosure. In one illustrative embodiment the system may include an illumination subsystem configured for directing light generated by an illumination source to the sample. In one illustrative embodiment the system may include an image sensor positioned in a path of light from the sample. In one illustrative embodiment the image sensor may include a silicon layer configured to generate electron-hole pairs based on the light from the sample being incident on a light-sensitive area of the silicon layer. In one illustrative embodiment the image sensor may include a plurality of circuits formed on a first side of the silicon layer. In one illustrative embodiment the circuits may include at least one channel and first gate electrodes configured to control electron accumulation in the at least one channel. In one illustrative embodiment the image sensor may include a plurality of sensing nodes electrically connected to at least one circuit of the circuits, the sensing nodes formed on the first side of the silicon layer adjacent to the circuits. In one illustrative embodiment each sensing node may include a floating diffusion structure connected to one of the at least one channel of the circuits and an output circuit of the image sensor. In one illustrative embodiment each sensing node may include a charge reset structure configured to remove a charge from the floating diffusion structure. In one illustrative embodiment the floating diffusion structure may be configured to convert the charge responsive to the electron accumulation to a voltage proportional to an amount of the charge and dependent on a capacitance of the floating diffusion structure. In one illustrative embodiment the output circuit may be configured to generate output responsive to the voltage output by the floating diffusion structure. In one illustrative embodiment each sensing node may include a noise-cancellation gate electrode adjacent to the floating diffusion structure and configured to be driven by a noise-cancellation signal. In one illustrative embodiment the system may include at least one analog-to-digital converter (ADC) configured to generate digital image data values by digitizing corresponding voltage outputs generated on the sensing nodes. In one illustrative embodiment the system may include at least one digital signal processor (DSP) configured to receive and evaluate the digital image data values. In one illustrative embodiment the system may include a timing generator configured to generate charge transfer clock reset clock and the noise-cancellation signal utilized to drive the image sensor. In one illustrative embodiment the DSP may be configured to analyze the digital image data values to extract their frequency components and an amplitude of the frequency components. In one illustrative embodiment the timing generator may be configured to vary each noise-cancellation signal applied to each noise-cancellation gate electrode of each of the sensing nodes based on the frequency components and the amplitude of the frequency components received by the DSP to cancel a feedthrough caused on the voltage outputs generated on the sensing nodes.

In one illustrative embodiment the system may be configured as an inspection system and the information for the sample may include information for defects detected on the sample based on the output.

An image sensor is disclosed in accordance with one or more illustrative embodiments of the present disclosure. In one illustrative embodiment, the image sensor includes a silicon layer configured to generate electron-hole pairs when light is incident on a light-sensitive area of the silicon layer. In another illustrative embodiment, the image sensor includes a plurality of circuits formed on a first side of the silicon layer. In another illustrative embodiment, the plurality of circuits include a first channel and first gate electrodes configured to control electron accumulation in the first channel in response to generation of the electron-hole pairs. In another illustrative embodiment, the plurality of circuits include a resistive gate electrode formed on the first side of the silicon layer adjacent to the first gate electrodes and outside of the light-sensitive area and formed by a resistive gate structure. In another illustrative embodiment, the resistive gate structure includes a channel electrically connected to the first channel of the plurality of circuits and to a first sensing node of the image sensor. In another illustrative embodiment, the resistive gate structure includes electrical connections configured to control a voltage in the channel of the resistive gate electrode to direct the electron accumulation from the channel of the resistive gate electrode near the first gate electrodes to the channel near the first sensing node. In another illustrative embodiment, the plurality of circuits include a first sensing node formed on the first side of the silicon layer adjacent to the resistive gate electrode. In another illustrative embodiment, the first sensing node includes a first floating diffusion structure connected to the first channel of the plurality of circuits and a first output circuit of the image sensor. In another illustrative embodiment, the first sensing node includes a first charge reset structure configured to remove a charge from the first floating diffusion structure. In another illustrative embodiment, the first floating diffusion structure is configured to convert the charge responsive to the electron accumulation to a voltage proportional to an amount of the charge and dependent on a capacitance of the first floating diffusion structure. In another illustrative embodiment, the first output circuit is configured to generate output responsive to the voltage output by the first floating diffusion structure.

In another illustrative embodiment, the image sensor may be configured as a charge-coupled device.

In another illustrative embodiment, the image sensor may be configured as a backside illuminated charge-coupled device.

In another illustrative embodiment, the image sensor may be configured as a charge-coupled device further configured to function as a time-delay integration sensor.

In another illustrative embodiment, the plurality of circuits may be configured as charge-coupled device circuits.

In another illustrative embodiment, the silicon layer may be a silicon epitaxial layer.

In another illustrative embodiment, the silicon layer may be a silicon epitaxial layer and may include intrinsic or p-type doped silicon with a dopant concentration less than 10¹⁴ cm⁻³.

In another illustrative embodiment, the first channel of the plurality of circuits may include an n-type doped buried channel.

In another illustrative embodiment, the image sensor may further include a thin p-type layer with a dopant concentration at least ten times higher than a dopant concentration of the silicon layer, the thin p-type layer being disposed on a second side of the silicon layer opposite to the first side.

In another illustrative embodiment, the image sensor may further include an antireflection layer disposed on a second side of the silicon layer opposite to the first side.

In another illustrative embodiment, the first sensing node may further include a noise-cancellation gate electrode adjacent to the first floating diffusion structure and configured to be driven by a noise-cancellation signal.

In another illustrative embodiment, the image sensor may further include a second channel and third gate electrodes configured to control electron accumulation in the second channel in response to generation of the electron-hole pairs and a fourth gate electrode formed on the first side of the silicon layer adjacent to the third gate electrodes and outside of the light-sensitive area and formed by a second resistive gate structure. In another illustrative embodiment, the second resistive gate structure may include a channel electrically connected to the second channel of the plurality of circuits and to a second sensing node of the image sensor and electrical connections configured to control a voltage in the channel of the fourth gate electrode to direct the electron accumulation from the channel of the fourth gate electrode near the third gate electrodes to the channel near the second sensing node. In another illustrative embodiment, the image sensor may further include the second sensing node formed on the first side of the silicon layer adjacent to the fourth gate electrode. In another illustrative embodiment, the second sensing node may include a second floating diffusion structure connected to the second channel of the plurality of circuits and a second output circuit of the image sensor. In another illustrative embodiment, the second sensing node may include a second charge reset structure configured to remove a charge from the second floating diffusion structure. In another illustrative embodiment, the second floating diffusion structure is configured to convert the charge responsive to the electron accumulation to a voltage proportional to an amount of the charge and dependent on a capacitance of the second floating diffusion structure. In another illustrative embodiment, the second output circuit is configured to generate output responsive to the voltage output by the second floating diffusion structure.

A system configured for determining information for a sample is disclosed in accordance with one or more illustrative embodiments of the present disclosure. In one illustrative embodiment, the system includes an illumination subsystem configured for directing light generated by an illumination source to the sample. In another illustrative embodiment, the system includes an image sensor positioned in a path of light from the sample. In another illustrative embodiment, the image sensor includes a silicon layer configured to generate electron-hole pairs when the light from the sample is incident on a light-sensitive area of the silicon layer. In another illustrative embodiment, the image sensor includes a plurality of circuits formed on a first side of the silicon layer. In another illustrative embodiment, the plurality of circuits include a first channel and first gate electrodes configured to control electron accumulation in the first channel in response to generation of the electron-hole pairs. In another illustrative embodiment, the plurality of circuits include a resistive gate electrode formed on the first side of the silicon layer adjacent to the first gate electrodes and outside of the light-sensitive area and formed by a resistive gate structure. In another illustrative embodiment, the resistive gate structure includes a channel electrically connected to the first channel of the plurality of circuits and to a first sensing node of the image sensor. In another illustrative embodiment, the resistive gate structure includes electrical connections configured to control a voltage in the channel of the resistive gate electrode to direct the electron accumulation from the channel of the resistive gate electrode near the first gate electrodes to the channel near the first sensing node. In another illustrative embodiment, the plurality of circuits include a first sensing node formed on the first side of the silicon layer adjacent to the resistive gate electrode. In another illustrative embodiment, the first sensing node includes a first floating diffusion structure connected to the first channel of the plurality of circuits and a first output circuit of the image sensor. In another illustrative embodiment, the first sensing node includes a first charge reset structure configured to remove a charge from the first floating diffusion structure. In another illustrative embodiment, the first floating diffusion structure is configured to convert the charge responsive to the electron accumulation to a voltage proportional to an amount of the charge and dependent on a capacitance of the first floating diffusion structure. In another illustrative embodiment, the first output circuit is configured to generate output responsive to the voltage output by the first floating diffusion structure. In another illustrative embodiment, the system includes a controller configured for determining the information for the sample based on the output.

In another illustrative embodiment, the system may be configured as an inspection system and the information for the sample may include information for defects detected on the sample based on the output.

In another illustrative embodiment, the image sensor may further include a second channel and third gate electrodes configured to control electron accumulation in the second channel in response to generation of the electron-hole pairs. In another illustrative embodiment, the image sensor may further include a fourth gate electrode formed on the first side of the silicon layer adjacent to the third gate electrodes and outside of the light-sensitive area and formed by a second resistive gate structure. In another illustrative embodiment, the second resistive gate structure may include a channel electrically connected to the second channel of the plurality of circuits and to a second sensing node of the image sensor and electrical connections configured to control a voltage in the channel of the fourth gate electrode to direct the electron accumulation from the channel of the fourth gate electrode near the third gate electrodes to the channel near the second sensing node. In another illustrative embodiment, the image sensor may further include the second sensing node formed on the first side of the silicon layer adjacent to the fourth gate electrode. In another illustrative embodiment, the second sensing node may include a second floating diffusion structure connected to the second channel of the plurality of circuits and a second output circuit of the image sensor. In another illustrative embodiment, the second sensing node may include a second charge reset structure configured to remove a charge from the second floating diffusion structure. In another illustrative embodiment, the second floating diffusion structure is configured to convert the charge responsive to the electron accumulation to a voltage proportional to an amount of the charge and dependent on a capacitance of the second floating diffusion structure. In another illustrative embodiment, the second output circuit is configured to generate output responsive to the voltage output by the second floating diffusion structure.

In another illustrative embodiment, the first sensing node may further include a noise-cancellation gate electrode adjacent to the first floating diffusion structure and configured to be driven by a noise-cancellation signal.

A method of inspecting a sample is disclosed in accordance with one or more illustrative embodiments of the present disclosure. In one illustrative embodiment, the method may include directing and focusing light onto the sample. In another illustrative embodiment, the method may include receiving light from the sample and directing received light to an image sensor including a silicon layer configured to generate electron-hole pairs when light is incident on a light-sensitive area of the silicon layer. In another illustrative embodiment, the image sensor may include a plurality of circuits formed on a first side of the silicon layer including a first channel and first gate electrodes configured to control electron accumulation in the first channel in response to generation of the electron-hole pairs. In another illustrative embodiment, the image sensor may include a resistive gate electrode formed on the first side adjacent to the first gate electrodes and outside the light-sensitive area by a resistive gate structure including a channel electrically connected to the first channel and to a first sensing node of the image sensor and electrical connections configured to control a voltage in the channel of the resistive gate electrode to direct electron accumulation from the channel of the resistive gate electrode near the first gate electrodes to the channel near the first sensing node. In another illustrative embodiment, the first sensing node may be formed on the first side adjacent to the resistive gate electrode and may include a first floating diffusion structure connected to the first channel and a first output circuit of the image sensor and a first charge reset structure configured to remove a charge from the first floating diffusion structure. In another illustrative embodiment, the first floating diffusion structure may be configured to convert the charge to a voltage proportional to an amount of the charge and dependent on a capacitance of the first floating diffusion structure and the first output circuit may be configured to generate output responsive to the voltage output by the first floating diffusion structure. In another illustrative embodiment, the method may include moving the sample relative to the light simultaneously with receiving. In another illustrative embodiment, the method may include driving the first gate electrodes with charge transfer clock signals synchronized to the moving of the sample relative to the light to transfer electron accumulation from one of the first gate electrodes to an adjacent first gate electrode and to the resistive gate electrode. In another illustrative embodiment, the method may include driving the resistive gate electrode with constant voltages that are more positive near the first sensing node compared to near the first gate electrodes to transfer electron accumulation from the channel of the resistive gate electrode near the first gate electrodes to the channel near the first sensing node and to the first sensing node adjacent to the resistive gate electrode. In another illustrative embodiment, the method may include utilizing a first readout circuit including an analog-to-digital converter coupled to the first output circuit to convert the voltage output by the first sensing node to a digital number.

In one illustrative embodiment, the first sensing node may include a noise-cancellation gate electrode adjacent to the first floating diffusion structure and configured to be driven by a noise-cancellation signal.

In one illustrative embodiment, the image sensor may include a second channel and third gate electrodes configured to control electron accumulation in the second channel in response to generation of the electron-hole pairs. In another illustrative embodiment, the image sensor may include a fourth gate electrode formed on the first side adjacent to the third gate electrodes and outside the light-sensitive area by a second resistive gate structure including a channel electrically connected to the second channel and to a second sensing node of the image sensor and electrical connections configured to control a voltage in the channel of the fourth gate electrode to direct electron accumulation from the channel of the fourth gate electrode near the third gate electrodes to the channel near the second sensing node. In another illustrative embodiment, the image sensor may include the second sensing node formed on the first side adjacent to the fourth gate electrode and may include a second floating diffusion structure connected to the second channel and a second output circuit of the image sensor and a second charge reset structure configured to remove a charge from the second floating diffusion structure. In another illustrative embodiment, the second floating diffusion structure may be configured to convert the charge to a voltage proportional to an amount of the charge and dependent on a capacitance of the second floating diffusion structure and the second output circuit may be configured to generate output responsive to the voltage output by the second floating diffusion structure. In another illustrative embodiment, the method may include driving the third gate electrodes with charge transfer clock signals synchronized to the moving of the sample relative to the light to transfer electron accumulation from one of the third gate electrodes to an adjacent third gate electrode and to the fourth gate electrode. In another illustrative embodiment, the method may include driving the fourth gate electrode with constant voltages that are more positive near the second sensing node compared to near the third gate electrodes to transfer electron accumulation from the channel of the fourth gate electrode near the third gate electrodes to the channel near the second sensing node and to the second sensing node adjacent to the fourth gate electrode.

In one illustrative embodiment, the method may include utilizing a second readout circuit including an analog-to-digital converter coupled to the second output circuit to convert the voltage output by the second sensing node to a digital number.

In one illustrative embodiment, the method may include driving the first gate electrodes with a sinusoidal waveform.

In one illustrative embodiment, the method may include driving the first charge reset structure of the first sensing node with a voltage following a sinusoidal waveform over time.

In one illustrative embodiment, the method may include driving the third gate electrodes with the same sinusoidal waveform as the first gate electrodes.

In one illustrative embodiment, the method may include driving the fourth gate electrode with the same constant voltages as the resistive gate electrode.

In another illustrative embodiment, the method may include driving the second charge reset structure with the same sinusoidal waveform as the first charge reset structure.

In one illustrative embodiment, the second sensing node may include a noise-cancellation gate electrode adjacent to the second floating diffusion structure and configured to be driven by a second noise-cancellation signal.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF THE DRAWINGS

The numerous advantages of the disclosure may be better understood by those skilled in the art by reference to the accompanying figures.

FIG. 1A illustrates conventional driving clocks, including charge transfer clocks and a reset clock, and output signal waveforms.

FIGS. 1B and 1C illustrate schematic diagrams of conventional image sensors used with inspection systems in which sensing nodes are electrically connected to two or more columns of pixels.

FIGS. 2A and 2B illustrates schematic diagrams depicting side, cross-sectional views of an image sensor configured as a backside-illuminated charge-coupled device (CCD) that includes a sensing node with a reset structure including a noise-cancellation gate structure partially overlapping the reset gate structure and the image sensor sensing node, in accordance with one or more embodiments of the present disclosure.

FIG. 3 illustrates a schematic diagram depicting a top view and a cross-sectional side view of a sensing node where the noise-cancellation gate is placed adjacent to and partially overlapping with the sensing node region, in accordance with one or more embodiments of the present disclosure.

FIGS. 4A and 4B illustrate driving waveforms for the clock signals and sensor output signals, in accordance with one or more embodiments of the present disclosure.

FIGS. 5A, 5B, and 5C illustrate driving waveforms for the clock signals and sensor output signals in the systems, circuits, and methods described herein, in accordance with one or more embodiments of the present disclosure.

FIG. 6 illustrates an imaging apparatus including an image sensor, a timing generator for the image sensor driving clocks, analog-to-digital conversion, digital signal processing, and an external unit for image sensor control, data processing and storage, in accordance with one or more embodiments of the present disclosure.

FIG. 7 illustrates a simplified block diagram of an optical system including one or more of the image sensors and a plurality of circuits, in accordance with one or more embodiments of the present disclosure.

FIG. 8 illustrates a schematic diagram illustrating two image sensor pixel circuits, each provided with a sensing node, a reset structure, and a noise-cancellation gate structure, in accordance with one or more embodiments of the present disclosure.

FIG. 9 illustrates a schematic diagram of an image sensor in which a resistive gate charge transfer structure is electrically connected to each column of pixels and to a sensing node, in accordance with one or more embodiments of the present disclosure.

### DETAILED DESCRIPTION

The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure. Reference will now be made in detail to the subject matter disclosed, which is illustrated in the accompanying drawings.

Embodiments of the present disclosure are directed to an improvement in image sensors for semiconductor inspection systems to enable readout of low noise signals at high readout speed. Embodiments may implement a sensing node including a reset structure driven by a sinusoidal reset clock, and an additional gate structure driven with a signal of appropriate/corresponding/inverse amplitude and phase to cancel the coupling of the sinusoidal reset clock on the sensor output signal. Such a signal may be referred to as a noise-cancellation signal. Alternatively, and/or in addition, embodiments may implement a sensing circuit electrically connected to each column of sensor pixels and operated with non-pulsed, rather than pulsed, driving signals. For example, embodiments may include a resistive gate using non-pulsed signals to move charge out of pixels to further reduce noise. For instance, constant direct current (DC) and/or smooth, near constant signals may be used.

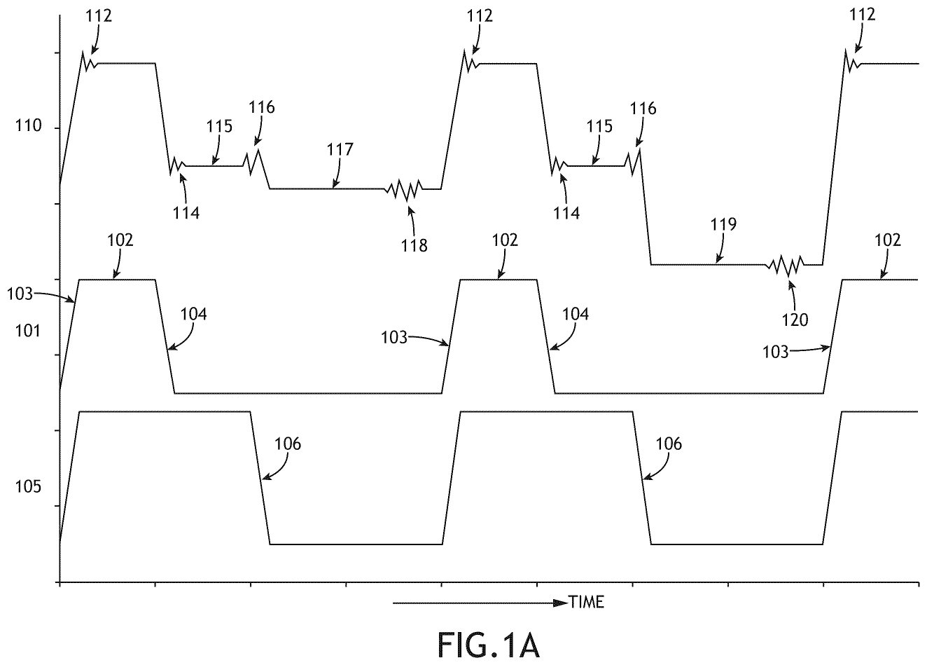

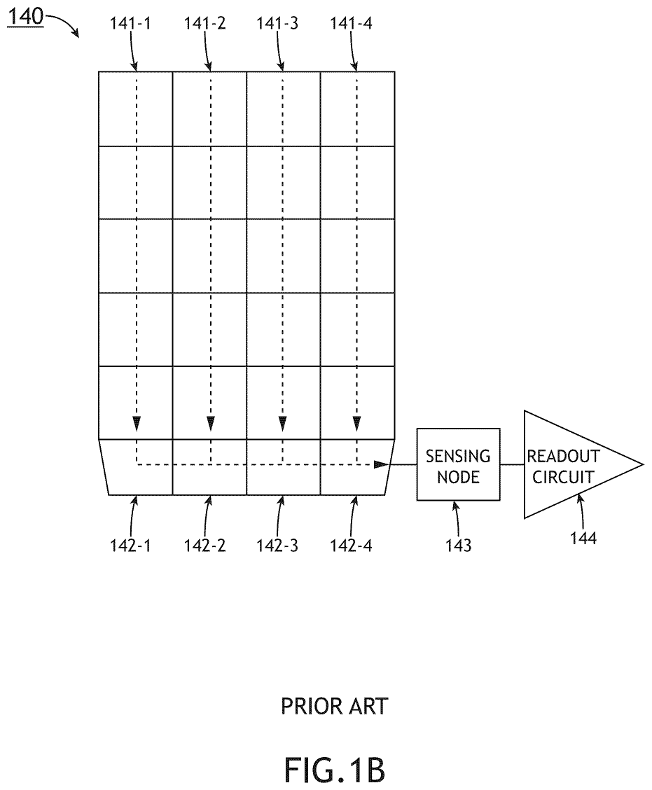

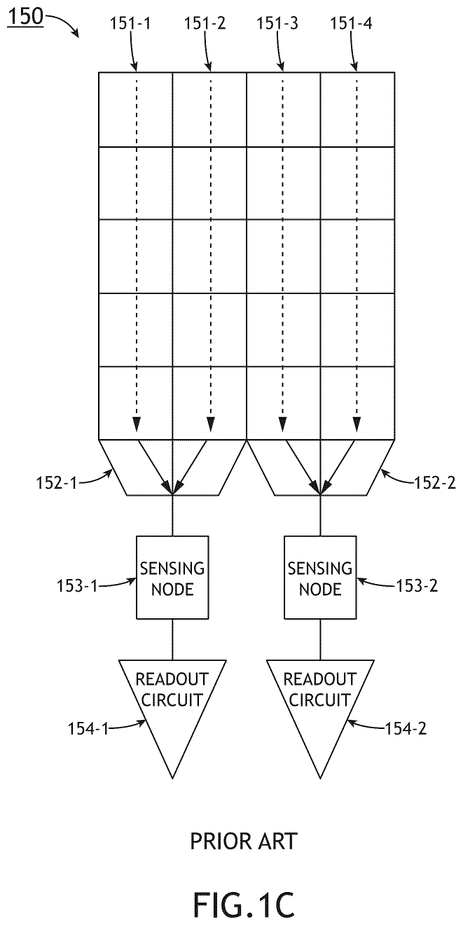

FIG. 1A illustrates a limitation of conventional image sensors and driving circuits. FIG. 1A illustrates the timing of the signal readout from an image sensor's sensing node. Value 110 represents the output voltage of the image sensor as a function of time for two consecutive pixel readouts. The two consecutive pixel readouts could be for signal charges from different, consecutive image sensor pixels as is typically the case in CCD image sensors, where a sensing node reads out the signals from one or more arrays of pixels, or for signal charges in the same pixel, as is typically the case in Complementary Metal-Oxide-Semiconductor (CMOS) image sensors or other sensors that implement a sensing node in each pixel. Value 101 represents the voltage of the reset clock as a function of time. The reset clock is a driving signal that resets the image sensor's sensing node after each pixel readout to prepare it for the next pixel readout. Value 105 represents the voltage of an image sensor's driver clock signal which transfers the signal charge from the image sensor's active elements to the image sensor's sensing node, and that we shall refer to as the charge transfer clock. The charge transfer clock 105 may also be referred to as a charge transfer signal, charge transfer clock voltage, or the like. The vertical axis of FIG. 1A represents voltage in arbitrary units, and the horizontal axis represents time. The vertical scalings of the voltages of the output signal 110, the reset clock 101, and the charge transfer clock 105 are not necessarily equal. The vertical offsets in the figure between the voltages of the output signal 110, the reset clock 101, and the charge transfer clock 105 are simply for clarity and do not imply that one voltage must be more positive or more negative than another.

When the voltage of the reset clock 101 is high (positive) as shown at voltage 102, the signal charge from the prior pixel readout is discharged. When the voltage of the reset clock 101 is lowered, output signal 110 settles down to a reset level shown as reference voltage 115. The signal charge for the next pixel readout is then transferred to the image sensor's sensing node by charge transfer clock 105 and is sensed as a signal level shown as voltage 117.

Output signal 110 illustrates several practical issues that can degrade the signal-to-noise ratio and accuracy of an output signal 110 of an image sensor, particularly when the image sensor is operated at high speed as is required for inspection and metrology applications in semiconductor and related industries. When the reset clock 101 switches from a low voltage to a high voltage as shown at transition 103, some of that voltage swing is coupled to the output signal 110 because the reset transistor is necessarily physically located adjacent to the sensing node. This coupling destabilizes the output signal 110 as shown at portion 112. Furthermore, when the reset clock 101 goes low as shown at transition 104, that high-to-low transition 104 similarly couples to the output signal 110 and destabilizes it as shown at portion 114. After some time, the output signal 110 settles down and stabilizes at the reset level shown as reference voltage 115. The charge from the next pixel readout is typically transferred to the sensing node by driving the charge transfer clock 105 with a voltage transition from a higher voltage to a lower voltage, as shown at transition 106. As with the reset clock 101, this high-to-low transition 106 for the charge transfer clock 105 can couple with and destabilize the output signal 110, as shown at portion 116. When the transfer of charge from the next pixel readout to the sensing node is completed, the output voltage decreases from the reference voltage 115—because the signal includes electrons and is, hence, a negative charge—to a level such as voltage 117 for the first pixel readout or voltage 119 for the second pixel readout. These levels are used to measure the voltages corresponding to the photogenerated charges in the corresponding pixels. The voltage signal corresponding to the charge in the first pixel readout is proportional to the difference between voltages 117 and 115, and the voltage signal corresponding to the charge in the second pixel readout is proportional to the difference between voltages 119 and 115. Usually Correlated Double Sampling (CDS) is used to measure the difference between the reference voltage 115 and the signal voltages such as voltages 117 and 119. Correlated Double Sampling is a well-known technique and is described in earlier publications.

In FIG. 1A, voltage 119 corresponds to a larger signal compared to voltage 117. Such voltages 117, 119 may be non-zero even in the absence of light-induced photogeneration in the sensor pixels. The creation of a voltage level such as the smaller voltage 117 may be due solely to the coupling of the charge transfer clock 105 (e.g., the charge transfer clock voltage) to the output signal 110 of the image sensor.

Voltages 117 and 119 may be affected by disturbances due to interference and noise sources from the image sensor circuits and/or the readout circuits, as shown at portion 118 for the first pixel readout and portion 120 for the second pixel readout. The magnitude of these noise contributions depends also on the bandwidth of the readout circuits of the image sensor. For operation at high speed, such as required in semiconductor inspection and metrology applications, the image sensor's readout circuits typically require high readout bandwidth (such as analog bandwidth approximately 30 MHz or more) and are thus prone to increased readout noise.

Furthermore, when the image sensor's output signal 110 needs to be read out at high speed, such as a speed of about 10 MHz or more, there is only a short time for the output signal 110 to settle to the reference voltage 115 and the signal voltages such as voltages 117 and 119. For example, at 50 MHz, the total time for one pixel readout is 20 nanoseconds (ns). The reset clock 101 pulses must necessarily be much shorter than this with rise and fall transition times of, at most, 1-2 ns. Such short pulses with fast rise and fall times necessarily cause significant destabilization of the output signal 110. Only a few nanoseconds are available for the output signal 110 to settle at its reset level. Furthermore, the transfer of charge from the image sensor pixel(s) to the sensing node, regulated by charge transfer clocks such as charge transfer clock 105, must necessarily happen also in a time period on the order of a few ns, so that the output signal 110 has only a few nanoseconds to settle at its signal level. In some cases, the image sensor's output signal 110 may not have enough time to fully stabilize, leading to image data values with low signal-to-noise ratios due, in part, to noise components induced by the reset clock 101 and the charge transfer clock 105 and their fast signal transitions.

In the example of FIG. 1A, only one charge transfer clock 105 and its effect on output signal 110 are shown for simplicity. In practical image sensors suitable for semiconductor inspection systems, two or more charge transfer clocks may be needed to transfer the signal charges from the image sensor's pixels to the output. This is the typical case of CCD image sensors configured as a two-dimensional (2D) array of pixels, where one or more columns of pixels may be connected to the same sensing node and readout circuit. In such CCD image sensors, charge transfer clocks may be connected across the whole array of pixels and used to transfer charge from one pixel to the next within one column or multiple columns of pixels simultaneously. Such one or multiple columns of pixels may be connected to a readout register including additional CCD gates and requiring additional charge transfer clocks to transfer the pixel charges to sensing nodes and readout circuits electrically connected to the sensing nodes. In practical CCD image sensors, more than one readout register may be provided and connected to one or more sensing nodes and readout circuits connected to the sensing nodes.

All these charge transfer clocks, both those required to transfer pixel charges along the columns of pixels and to the readout registers and those required to further transfer the pixel charges to the sensing nodes, can in principle couple and cause disturbances to the CCD image sensor's output signals, similar to what is described above with reference to FIG. 1A and the effect of the charge transfer clock 105 on the image sensor's output signal 110. Also similar to what is described above, in applications where the CCD image sensor needs to be read out at high speed, the fast voltage transitions of such charge transfer clocks 105, or at least of a part of such charge transfer clocks 105, must necessarily happen in time periods on the order of a few nanoseconds and can destabilize the CCD output signal, leaving little time for it to settle at its signal levels and inducing noise components that can further affect the noise and therefore the signal-to-noise ratio of the image.

Other noise components can be introduced by the image sensor's readout circuits, especially when they are provided with high analog bandwidth, as necessary to read out image sensor signals at high speed. In the case of un-patterned (i.e., bare) or monitor wafer inspection operating at relatively low light levels, noise read from an imaging sensor may be the limiting system noise source.

FIGS. 1B and 1C illustrate schematic diagrams of image sensors 140, 150 used with conventional inspection systems in which sensing nodes are electrically connected to two or more columns of pixels, in accordance with one or more embodiments of the present disclosure.

In FIG. 1B, image sensor 140 includes four columns 141-1, 141-2, 141-3, and 141-4 that each include five pixels. Although four columns of pixels are shown, this is a nonlimiting number and the image sensor 140 may include any number of columns such as one or more columns of pixels. In addition, although each column shown includes five pixels, this is a nonlimiting number and each column may include any number of one or more pixels. For example, each column may include two or more pixels.

Charge transfer clocks may be connected across the whole array and used to transfer charge from one pixel to the next within all, or a group of, columns simultaneously. In FIG. 1B, pixel charges are thus transferred along columns 141-1, 141-2, 141-3, and 141-4, until they are collected by circuits 142-1, 142-2, 142-3, and 142-4, respectively, at the bottom of the columns and electrically connected to them. Circuits 142-1, 142-2, 142-3, and 142-4 may include CCD gates and readout registers. Typically, such circuits are electrically connected to each other and driven by additional charge transfer clocks to transfer the pixel charges from one circuit to another until a last circuit such as 142-4 is electrically connected to a sensing node such as 143. Sensing node 143 is in turn electrically connected to a readout circuit such as 144, which may include buffer amplifiers and/or Analog-to-Digital Converters (ADCs).

In practical CCD image sensors, more than one sensing circuit may be provided and connected to one or more sensing nodes and readout circuits at the bottom of one or more pixel columns. A possible arrangement with multiple sensing nodes and readout circuits is illustrated in FIG. 1C, where image sensor 150 includes four columns 151-1, 151-2, 151-3, and 151-4 of five pixels each. The number of columns and the number of pixels in each column may vary as described above. In the arrangement of FIG. 1C, charge transfer clocks are connected to the pixel array and transfer the pixel charges from columns 151-1 and 151-2 to a common circuit 152-1, and the pixel charges from columns 151-3 and 151-4 to another circuit 152-2. Circuits 152-1 and 152-2 may include CCD gates and readout registers, and are separately connected to sensing nodes 153-1 and 153-2, respectively. In such an arrangement, circuit 152-1 may need additional charge transfer clocks, other than those needed to transfer the pixel charges along columns 151-1 and 151-2 connected to it, to alternately transfer the charges from columns 151-1 and 151-2 to sensing node 153-1. Similarly, circuit 152-2 may need additional charge transfer clocks to alternately transfer the charges from columns 151-3 and 151-4 connected to it to sensing node 153-2. The charge transfer clocks connected to circuits 152-1 and 152-2 may be the same or different. Further, sensing nodes 153-1 and 153-2 are typically electrically connected to separate readout circuits 154-1 and 154-2, respectively.

With reference to FIGS. 1B and 1C, all the additional charge transfer clocks, other than those needed to transfer the pixel charges along the pixel columns, can in principle couple and cause disturbances to the CCD image sensor output signals, similar to what is described above with reference to FIG. 1A and the effect of charge transfer clock 105 on the CCD output signal 110. Also similar to what is described above, in applications where the CCD output signal needs to be read out at high speed, the fast voltage transition of such additional charge transfer clocks, or at least of a part of such additional charge transfer clocks, may need to happen in time periods on the order of a few nanoseconds and can destabilize the CCD output signal. This may leave little time for the CCD output signal to settle at its signal levels and induce noise components that can further affect the CCD noise and therefore the signal-to-noise ratio of the image.

Other noise components can be introduced by the CCD readout circuits, especially when they are provided with high analog bandwidth, as necessary to read out CCD output signals at high speed. In the case of un-patterned (bare) or monitor wafer inspection operating at relatively low light levels, noise from an imaging sensor may be the limiting system noise source.

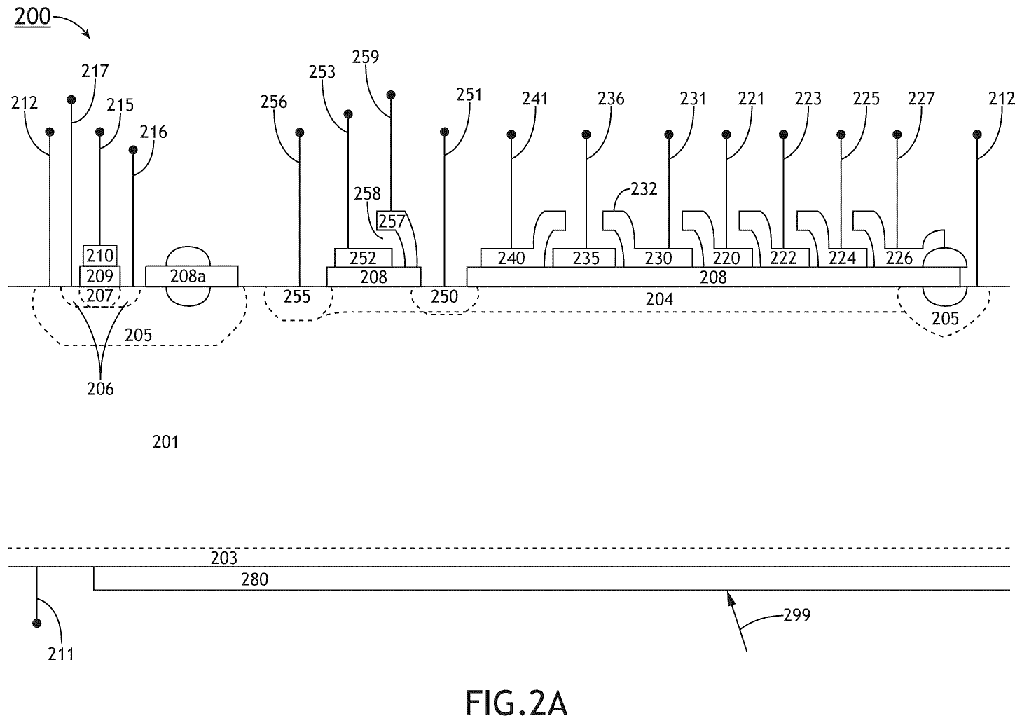

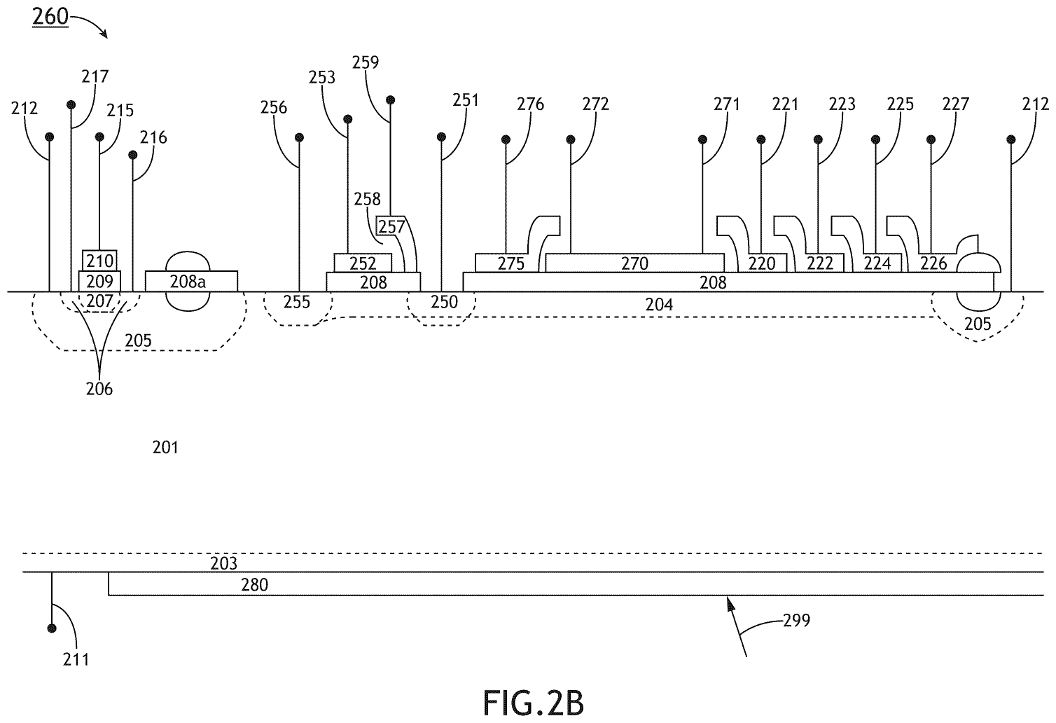

FIG. 2A illustrates some aspects of the design, fabrication, and operation of an image sensor 200 configured as a backside-illuminated charge-coupled device (CCD) image sensor implementing a sensing node 250 electrically connected to the image sensor pixel gate electrodes and to additional gate electrodes used to transfer the photogenerated signal charge from the pixel gate electrodes to the sensing node. When light 299 is absorbed in the silicon, electron-hole pairs are created in response. In this manner, light is incident on the backside of image sensor 200 (also referred to herein as the “second side”), which is opposite to the frontside (also referred to herein as the “first side”) of the image sensor 200 on which the image sensor circuits (or pixels) are formed.

In embodiments, the image sensor 200 includes a silicon layer 201 configured to generate electron-hole pairs when light is incident on a light-sensitive area of the silicon layer 201. The silicon layer 201 may be configured to generate the electron-hole pairs in any suitable manner known in the art.

In embodiments, the silicon layer 201 includes a silicon epitaxial layer 201. In embodiments, the silicon layer 201 includes intrinsic or p-type doped silicon with a dopant concentration less than 10¹⁴ cm⁻³. For example, the silicon layer 201 may be manufactured on a highly doped p-type silicon substrate with a dopant concentration greater than about 10¹⁵ cm⁻³. As shown in FIG. 2A, the sensor may be fabricated in an intrinsic or lightly p-type doped silicon layer 201 with a thickness between a few micrometers and a few tens of micrometers.

In embodiments, the image sensor 200 includes a thin p+ layer 203 with a dopant concentration at least ten times higher than a dopant concentration of the silicon layer 201. The p+ layer 203 (e.g., p-type layer) may be disposed on the second side of the silicon layer 201 opposite to the first side of the silicon layer 201. In backside-illuminated image sensors, the backside (e.g., light-sensitive) surface of the silicon layer 201 is where light 299 is incident. The p+ layer 203 may include a substantially highly doped p+ layer 203 formed at the backside surface of silicon layer 201 by either ion implantation or drive-in of boron atoms from a thin boron layer deposited on the surface. Backside p+ layer 203 is “thin” in that it may be substantially shallow (e.g., between a few nanometers to tens of nanometers) to ensure suitable sensitivity to ultraviolet (UV), deep UV (DUV), vacuum UV (VUV), and extreme UV (EUV) light. Under prolonged exposure to UV, DUV, VUV, or EUV light, charges and traps may accumulate in the silicon dioxide at the backside surface of silicon layer 201 and can degrade the sensor performance. Shallow p+ layer 203 introduces fixed negative charges on the sensor backside, which prevents trapping of the photogenerated charge at defects and preserves sensitivity to UV, DUV, VUV, and EUV light. An optional electrical connection 211 may be made to the backside p+ layer 203 and used to apply a bias voltage to the backside p+ layer 203. For example, the optional electrical connection 211 may be configured as a ground connection to connect to an electrical ground of a system.

In embodiments, the image sensor 200 includes a protection or antireflection layer disposed on the second side of the silicon layer 201. For example, the protection or antireflection layer may include backside coating 280 deposited on the backside of silicon layer 201. Depending on the wavelengths of interest, backside coating 280 may include a substantially thin layer of pure boron or silicon dioxide (i.e., a layer thickness between a few nm and tens of nm), and/or one or more antireflection layers (e.g., including alumina, another oxide, or a fluoride) to reduce the sensor reflectivity and improve sensitivity at those wavelengths. For example, in addition to the ranges of doping levels and materials described herein, the backside coating 280 may be custom engineered to be highly sensitive to the wavelengths of interest of the systems described further herein in which the image sensors may be used.

The image sensor 200 may include a plurality of circuits formed on the first side of the silicon layer 201. The circuits may include at least one channel and first gate electrodes configured to control electron accumulation in the at least one channel in response to light-induced generation of the electron-hole pairs. In embodiments, the dielectric layer 208 is formed (e.g., grown) on the first surface of the silicon layer 201. The dielectric layer 208 may include a single dielectric material such as silicon dioxide, multiple layers of dielectric materials such as a silicon nitride layer on top of a silicon dioxide layer, or a three-layer stack such as silicon dioxide on silicon nitride on silicon dioxide. Suitable dielectric thicknesses may be in a range from 50 nm to 200 nm. Dielectric layer 208 may have openings etched into it as appropriate to allow electrical contact to the underlying silicon when needed. Multiple gate electrodes, which may be made of polysilicon, such as gate electrodes 220, 222, 224, 226, 230, 235, and 240 are formed (e.g., deposited and patterned) on top of dielectric layer 208. The gate electrodes 220, 222, 224, 226, 230, 235, and 240 may be separated from each other by dielectric material (not shown). Electrical connections such as electrical connections 221, 223, 225, 227, 231, 236, and 241 may be made to the gate electrodes 220, 222, 224, 226, 230, 235, and 240. In embodiments, the gate electrodes 220, 222, 224, 226, 230, 235, and 240 overlap one another, as shown for example at overlap portion 232, to control fringe electric fields near the edges of the gate electrodes 220, 222, 224, 226, 230, 235, and 240.

When light 299 is absorbed in the silicon layer 201, electron-hole pairs are created. Holes move to the backside surface where they recombine, while electrons are accelerated toward channel 204 formed by a n-type layer by the electric field generated across the image sensor 200 by the voltages applied to the gate electrodes on the frontside of the sensor, such as gate electrodes 220, 222, 224, and 226, which form a column of light-sensitive pixels. Although only four gate electrodes 220, 222, 224, and 226 are shown for clarity purposes, any number of gate electrodes may be used to form any number of light-collecting pixels, from one pixel per column (e.g., a line sensor) to thousands of pixels per column.

Potential differences may be applied to these gate electrodes 220, 222, 224, 226 via electrical connections 221, 223, 225, 227 to control where (e.g., under which gate) the collected light-generated electrons are accumulated in the channel 204 formed by n-type layer. Electrons will accumulate under the gate electrode with the maximum potential underneath it. For example, if electrical connection 227 connected to gate electrode 226 is at a voltage of +5V and electrical connection 225 connected to gate electrode 224 is at a voltage of −5V, electrons will accumulate under gate electrode 226.

Other than controlling the storage of charge, the gate electrodes are used to transfer the stored charge from one pixel to another. For example, if electrons are stored under gate electrode 226, raising the voltage on gate electrode 224 applied by electrical connection 225 to a more positive voltage than that applied to gate electrode 226 by electrical connection 227, and/or lowering the voltage on gate electrode 226 to a smaller (more negative) voltage than that applied to gate electrode 224, will move the electrons from gate electrode 226 to underneath gate electrode 224. The electrons can be subsequently moved from gate electrode 224 to gate electrode 222, then from gate electrode 222 to gate electrode 220, and so on, by varying the voltages applied to electrical connections 225, 223, and 221 appropriately.

As in CCD technology, the gate electrodes may be configured as two-phase, three-phase, or four-phase clocks (i.e., there are two, three, or four gates per pixel, respectively). Also, in a sensor suitable for semiconductor inspection such as a time-delay integration (TDI) sensor, the gate electrodes may be clocked at a rate that causes the charge to be transferred in synchrony with a moving image falling on the image sensor 200. For example, the gate electrodes may be clocked at a rate that is in synchrony with the motion of a stage on which the sample being inspected is held.

At one end of the light-sensitive pixel gate electrodes, for example when electrons are underneath gate electrode 220, electrons are moved to a first buffer gate (e.g., gate electrode 230, or buffer gate) by applying a higher voltage to electrical connection 231 connected to gate electrode 230 compared to a voltage applied to electrical connection 221 connected to gate electrode 220. A more positive voltage than that applied to gate electrode 230 (such as a few volts more positive) is then applied to a second buffer gate such as buffer gate electrode 235 by electrical connection 236, causing the electrons to move under the second buffer gate electrode 235. After this transfer, lowering the first buffer gate electrode 230 to a voltage less than that applied by electrical connection 221 to gate electrode 220 stops the transfer of electrons to the region under buffer gate electrode 235, and allows accumulation of electrons from the next image pixel, which can be later transferred to under buffer gate electrode 230 in a subsequent readout cycle.

In embodiments, image sensor 200 may include additional gate electrodes similar to gate electrode 240, each with an electrical connection such as electrical connection 241, forming a readout register that transfers the image signals from the pixel circuits to a sensing node such as sensing node 250 for charge-to-voltage conversion. Sensing node 250 may be configured as described further herein. The number of additional gate electrodes may vary from one to a few tens (e.g., at least forty), typically from 1 to 32, depending on the application for which the sensor will be used. The electrons are transferred from one gate electrode to another gate electrode of the readout register by sequencing the voltages applied to the gate electrodes appropriately, as is done in CCDs.

In embodiments, there may be no readout register and gate electrode 240 may be omitted, and electrons may be transferred directly from a buffer gate such as buffer gate electrode 235 to sensing node 250, which may be configured as described further herein.

In embodiments, at least one channel of the circuits includes an n-type doped buried channel. For example, the channel 204 formed by n-type layer, with a dopant concentration of about 10¹⁶ cm⁻³, may be formed just under the top (frontside) surface of silicon layer 201. When the image sensor 200 is properly biased, the channel 204 formed by n-type layer forms a buried channel that is used to collect and transfer electrons as described above. Either end of the channel 204 formed by n-type layer may include a p+ layer 205 which has a dopant concentration greater than or equal to about 2× the dopant concentration of the channel 204 formed by n-type layer. The p+ layer 205 is connected to ground by one or more electrical connections such as electrical connection 212, and it may be connected to ground in multiple locations. The p+ layer 205 may be referred to as a p-well, p+ type layer, or the like.

In embodiments, the image sensor 200 is configured as a CCD. In one example, the image sensor 200 is configured as a backside-illuminated CCD. In another example, the image sensor 200 is configured as a complementary metal-oxide-semiconductor (CMOS) sensor. In another example, the image sensor 200 is configured as a backside-illuminated CMOS sensor.

In embodiments, the circuits are configured as CCD circuits. In additional and/or alternative embodiments, the circuits are configured as metal-oxide semiconductor field-effect transistors (MOSFETs). In additional and/or alternative embodiments, the circuits are configured as CMOS circuits.

As described further above, the image sensor 200 may include CCD pixels and circuits on the front side of an intrinsic or lightly p-type doped silicon layer 201 and may incorporate a pure boron layer on its backside (illuminated) surface. Electrons generated by light at near-infrared (near-IR), visible, UV, DUV, VUV, extreme UV (EUV), and/or X-ray wavelengths are detected in the silicon layer 201 and collected by the CCD pixels on the front side of the silicon layer 201 due to the electric field generated across the silicon layer 201 by appropriate corresponding voltages applied to the CCD pixels. The electrons collected by the CCD pixels are transferred to a sensing node such as sensing node 250 configured to perform charge-to-voltage conversion and connected to CCD readout circuits. As described further herein, embodiments may include CCD sensors configured for semiconductor wafer, reticle, and printed circuit board (PCB) inspection.

In embodiments, the image sensor 200 is configured as a CCD configured to function as a time-delay integration (TDI) sensor. For example, the sensor embodiments described herein may be a CCD sensor used as a TDI sensor for wafer, reticle, and PCB inspection. Such an image sensor 200 may be configured so that the gate electrodes are clocked at a rate that causes the charge to be transferred in synchrony with a moving image falling on the image sensor 200, such as in synchrony with the motion of the stage on which the sample being inspected is held. For example, the image sensors 200 described herein may be configured as CCD sensors with one or more aspects of internal avalanche multiplication as described in U.S. Pat. No. 9,620,547, issued on Apr. 11, 2017, which is incorporated herein by reference in the entirety.

In embodiments, the image sensor 200 further includes the sensing node 250 formed on the first side of the silicon layer, adjacent to the circuits and outside of the light-sensitive area, and electrically connected to the circuits (e.g., formed by gate electrodes 220, 222, 224, 226, 235, and 240). Sensing node 250 is typically formed by a floating-diffusion structure, as is common in imaging devices, and is electrically connected to channel 204 of the image sensor's circuits so that it can receive the signal charges from them. The dopant concentration of the sensing node 250 is typically one or a few orders of magnitude higher than the channel 204 formed by the n-type layer. For example, the dopant concentration of the sensing node 250 may range from 10¹⁸ cm⁻³ to 10²¹ cm⁻³. The sensing node 250 may also be connected to a readout amplifier (e.g., by electrical connection 251) that buffers the voltage signal corresponding to the charge stored in the floating diffusion's capacitance to the image sensor output or an Analog-to-Digital Converter (ADC).

Sensing node 250 may also be connected to an adjacent charge reset structure, formed by a polysilicon gate such as gate electrode 252, patterned on top of dielectric layer 208 and channel 204. Dielectric layer 208 is typically formed by the same material and of the same thickness as the dielectric layer of the image sensor pixel circuits, but can also be formed by a different material and be of a different thickness. A reset gate voltage is typically applied to reset gate electrode 252 via electrical connection 253. The reset structure also includes n-type drain 255, adjacent to reset gate electrode 252 and electrically connected to channel 204. A fixed reset drain (RD) voltage is applied to n-type drain 255 by electrical connection 256.

In embodiments, after the voltage signal at sensing node 250 is read out by a readout amplifier, reset gate electrode 252 is biased to connect sensing node 250 to n-type drain 255 and thus to the RD voltage, typically higher than the sensing node voltage, so that charge is drained from the sensing node 250. The sensing node 250 is thus reset to the RD voltage. When reset is complete, the sensing node 250 is disconnected from the RD voltage by appropriately biasing reset gate electrode 252, so that the sensing node 250 can receive the next signal charges from the circuits of the image sensor 200.

In embodiments, an additional gate such as noise-cancellation gate electrode 257, or “noise-cancellation gate”, is formed above reset gate electrode 252 and isolated from sensing node 250 by dielectric layer 208. Noise-cancellation gate electrode 257 partially overlaps reset gate electrode 252, for example as shown at area 258, and is provided with an electrical connection such as connection 259 and may be driven by an appropriate corresponding signal (e.g., noise-cancellation signal) to mitigate the effect of the coupling of the voltage signal used to drive reset gate electrode 252 into sensing node 250. Note that the noise-cancellation signal and noise-cancellation gate electrode 257 may refer to cancelling the coupling caused by the voltage signal used to drive the reset gate electrode 252, but that such a cancellation is merely a non-limiting example. In embodiments, the noise-cancellation signal and noise-cancellation gate electrode 257 may be used to cancel any signal and/or any coupling, such as from any nearby elements outputting various signals. In this way, the noise-cancellation signal and noise-cancellation gate electrode 257 may cancel one or more of a combination of one or more capacitive couplings. For example, such capacitive couplings may be modeled, predicted, measured based on historical data, measured in real time, and/or known based on a design and cancelled with a corresponding noise-cancellation signal deterministically and/or dynamically in real time using any suitable method known in the art, such as a signal generator and/or circuit configuration configured to produce such an opposing noise-cancellation signal. In embodiments, the noise-cancellation gate electrode 257 is either biased at a constant voltage, for example the same voltage as the reset drain (RD) voltage, or driven with a waveform specially designed to optimize the removal of the coupling from the sensor output signal and improve sensor noise performance, as described further herein.

In conventional techniques, such as those used in conventional setups, a reset gate may simply be connected to a constant voltage (e.g., the RD voltage). This may reduce but not remove the coupling from only the reset clock. Such a configuration would not be configured to reduce or remove couplings from any other clocks. It is contemplated that in embodiments of the present disclosure, in contrast to conventional techniques, that driving the noise-cancellation gate electrode 257 with a specially designed waveform may reduce any number of one or more clock couplings from the sensor output signal.

Circuits for amplifying or processing the signals and controlling the image sensor 200 may be fabricated inside the light-sensitive area or adjacent to the light-sensitive area. Such a circuit is illustrated by the MOSFET transistor formed by source and drain implants 206, channel implant 207, gate dielectric 209, and gate electrode 210. Electrical connections such as electrical connections 215, 216, and 217 may be made to the MOSFET transistor's gate, source, and drain, respectively. Gate dielectric 209 may be substantially similar to dielectric layer 208 and may be formed at the same time, or gate dielectric 209 may be formed of different materials and/or different thicknesses than dielectric layer 208 as necessary to get the desired transistor characteristics. Even though only one transistor is illustrated in FIG. 2A for simplicity, such circuits may include a plurality of transistors. In embodiments, MOSFET transistors with a n-type channel are fabricated in a p+ layer 205 (e.g., p+ doped well) in order to electrically isolate them from currents in the silicon layer 201.

Some embodiments may include structure 208a, that may be substantially similar to dielectric layer 208 and may be formed at the same time. For example, structure 208a may be formed as a single dielectric layer that is then patterned to create separation between dielectric layer 208 and structure 208a. Alternatively, structure 208a may be formed of different materials and/or different thicknesses than dielectric layer 208 and/or gate dielectric 209 depending on, for example, the desired characteristics of structure 208a. Structure 208a may be an optional isolation structure formed between sensing node 250 and the output circuit and may be formed above p+ layer 205. In this manner, the isolation structure may separate the readout circuits from the sensor's active area and sensing node.

FIG. 2B illustrates an image sensor 260 including only a single buffer gate electrode 270, or “resistive gate electrode”, in accordance with one or more embodiments of the present disclosure.

The resistive gate electrode 270 may be formed by high-resistivity polysilicon and provided with multiple electrical connections (i.e., at least two) to control the voltage gradient along resistive gate electrode 270. The resistive gate electrode 270 may be referred to as a resistive buffer gate, resistive output gate, second gate, second gate electrode, or the like. FIG. 2B illustrates two of such electrical connections as electrical connection 271, placed in the region of resistive gate electrode 270 near the pixel circuits, and electrical connection 272, placed in the region of resistive gate electrode 270 near the sensing node of the image sensor 260. All other elements of FIG. 2B may be the same as in FIG. 2A and perform the same function. The voltage applied to electrical connection 272 is typically higher (i.e., more positive) than the voltage applied to electrical connection 271, so that a potential gradient is created at the region of channel 204 under resistive gate electrode 270. In this configuration, when the voltage applied to the last gate electrode 220 is lower than the voltage applied to electrical connection 271, the signal charge in channel 204 under gate electrode 220 is transferred to under resistive gate electrode 270, in the region of channel 204 under electrical connection 271. Due to the electric field generated by the potential gradient in channel 204 caused by the voltage difference between electrical connections 271 and 272, such signal charge will drift from the region of channel 204 under electrical connection 271 to the region of channel 204 under electrical connection 272, which is nearer to sensing node 250. In this way, electrical connections 271 and 272 may be configured to control a voltage in the region of the channel 204 to direct electron accumulation under the resistive gate electrode 270 from the pixel gate electrodes to the sensing node 250.

The resistive gate electrode 270 may thus be controlled using only constant, direct-current (DC) voltages, and not time-varying charge transfer clocks such as those described with reference to FIG. 1A, where the fast transitions of such time-varying charge transfer clocks couple with the image sensor output voltage and affect noise performance. Another way to characterize the voltages applied to resistive gate electrode 270 by electrical connections 272 and 271 is to define them as non-pulsed signals, which include direct-current (DC) constant voltages. Furthermore, the voltages applied to resistive gate electrode 270 may be characterized as not including fast time-varying signals such as those described with reference to FIG. 1A, where the fast transitions of such time-varying signals couple into the image sensor output voltage and affect noise performance.

Thus, transferring electrons from the image sensor pixel gate electrodes such as gate electrodes 220, 222, 224, and 226 to a sensing circuit using a resistive gate structure such as resistive gate electrode 270 provides a low-noise option that isolates the sensor output voltage from the time-varying signals controlling the sensor pixels. Such isolation will be improved by a longer resistive gate electrode 270, although there will be a tradeoff between the length of resistive gate electrode 270 and the speed at which the electron transfer under it will occur. For example, a twice-longer resistive gate electrode will require a twice-larger voltage gradient across it for the electric field in channel 204 and the consequent electron charge transfer speed to remain the same. In embodiments, high voltage gradients across the resistive gate electrode 270 may not be practical, as that would also result in too large a current across the resistive gate electrode 270 itself and flowing between electrical connections 271 and 272 and, hence, potentially too high of a generation of heat.

After the transfer of electrons from the last gate electrode 220 to the resistive gate electrode 270, increasing the voltage applied to the gate electrode 220 to a voltage larger than that applied by the electrical connection 271 to the first end of the resistive gate electrode 270 stops the transfer of electrons to the region under the resistive gate electrode 270, and allows accumulation of electrons from the next image pixel under the gate electrode 220.

It is noted here that, in FIG. 2B, the resistive gate electrode 270 is drawn as longer than gate electrodes 220, 222, 224, and 226 as that will be the case in typical embodiments. FIG. 2B is, however, not to scale, and other arrangements and dimensions are possible, while keeping in mind the tradeoff between the length of the resistive gate electrode 270 and the voltage gradient applied across the resistive gate electrode 270 by electrical connections 271 and 272.

Among the gate electrodes, the resistive gate electrode 270 will typically feature substantially higher resistivity compared to the other gates, in order for the voltage gradient between its ends, applied by electrical connections 271 and 272, to not result in significantly large currents within the resistive gate electrode 270.

As shown in FIG. 2B, the image sensor 260 may include an additional gate electrode such as gate electrode 275 between the resistive gate electrode 270 and then sensing node 250. Gate electrode 275 is provided with an electrical connection such as electrical connection 276 and may be biased at a constant voltage to control the potential in the region of the channel 204 between the resistive gate electrode 270 and the sensing node 250. In such an embodiment, the signal charge will transfer from under the resistive gate electrode 270 to the sensing node 250 when the potential under the gate electrode 275, controlled by the voltage applied to electrical connection 276, is larger (i.e., more positive) than the potential under the nearby region of the resistive gate electrode 270, controlled by the voltage applied to electrical connection 272, and the sensing node 250 is biased (e.g., reset) at a potential that is larger (i.e., more positive) than under gate electrode 275.

In embodiments, the gate electrode 275 may be omitted, and the signal charge may be transferred directly from under the resistive gate electrode 270, in the region under electrical connection 272, to sensing node 250, provided that the latter is biased at a potential that is larger (i.e., more positive) than under the resistive gate electrode 270.

In embodiments, the image sensor circuits are configured as a two-dimensional (2D) array of pixels and/or a linear array of pixels. For example, in CCD image sensors suitable for semiconductor inspection systems, multiple columns of pixels such as those depicted in FIG. 2A are laid out to form a 2D array of light-sensitive pixels. Clock and driving signals are connected across the whole array and used to transfer charge from one pixel to the next within all, or a group of, columns simultaneously. However, the configuration shown is for illustrative purposes only and embodiments may include pixels laid out in any other configuration and may include any number of more or fewer pixels than is shown.

In embodiments, the circuits are configured as multiple columns of pixels that include at least a first and second column of pixels. Each of the at least first and second column of pixels include one or more pixels. If a column includes more than one pixel, then the first pixel may be connected to the adjacent pixel (e.g., second pixel), the second pixel connected to the third pixel, and so on.

A sensing node such as sensing node 250 in FIG. 2A, including a reset structure formed by reset gate electrode 252, reset drain 255, and noise-cancellation gate electrode 257, may be electrically connected to each of such columns of pixels. In embodiments, such a sensing node 250 may be electrically connected directly to the first pixel in each column and thus connected to other pixels in the same column with that one pixel. In embodiments, the sensing node 250 is connected to the column of pixels by buffer gates such as buffer gate electrodes 230 and/or buffer gate electrodes 235. In embodiments, the sensing node is connected to the buffer gates and/or the column of pixels via an additional readout register such as readout register gate electrode 240 in FIG. 2A.

In embodiments, readout structures may be provided to connect two or more columns of pixels to a sensing node including a reset gate and a noise-cancellation gate. This may be accomplished by using additional readout registers such as gate electrode 240 in FIG. 2A and patterning them appropriately so as to electrically connect the first pixels of the two or more columns of pixels to the common sensing node.

A possible arrangement connecting two columns of pixels to a sensing node is described in U.S. Pat. No. 10,764,527, issued on Sep. 1, 2020, which is incorporated herein by reference in the entirety.

Another possible arrangement connecting three or more columns of pixels to a sensing node is described in U.S. Pat. No. 10,778,925, issued on Sep. 15, 2020, which is incorporated herein by reference in the entirety.

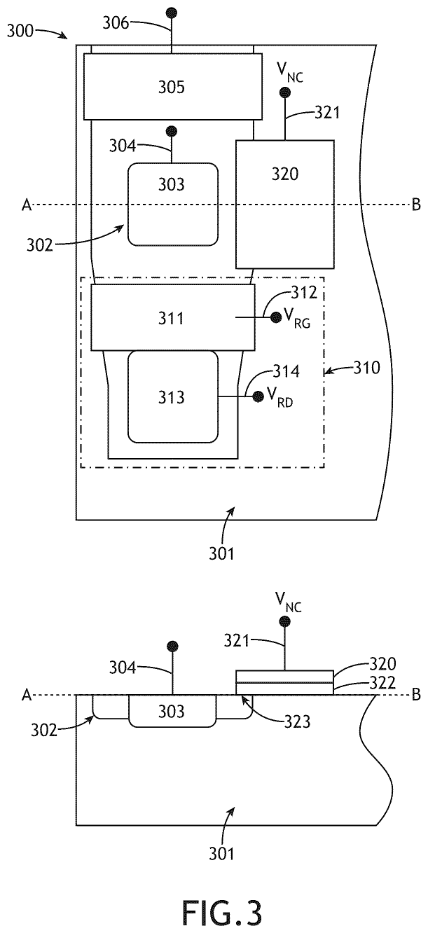

FIG. 3 illustrates a schematic diagram depicting a top view and a cross-sectional side view of a sensing node 300 where the noise-cancellation gate electrode 320 is placed adjacent to and partially overlapping with the sensing node region, in accordance with one or more embodiments of the present disclosure. The sensing node 300 includes a reset structure 310 and a noise-cancellation structure. The cross-sectional view of FIG. 3 corresponds to a cross-sectional cut along the line shown between A and B of the top view of FIG. 3. Sensing node 300 is formed on silicon substrate 301, typically configured as a silicon layer, on which channel 302 is implanted. Channel 302 performs a similar function as channel 204 in FIGS. 2A, 2B of transferring the signal charge from the image sensor pixels to a floating diffusion structure 303 that performs charge-to-voltage conversion. In FIG. 3, the signal charge is transferred from the region of channel 302 under gate electrode 305 to the floating diffusion structure 303 by driving an appropriate voltage on gate electrode 305 applied by electrical connection 306. In embodiments, gate electrode 305 represents the pixel of the image sensor if the image sensor is configured with one sensing node electrically connected directly to one or more of the image sensor pixels. In other embodiments, gate electrode 305 represents the last gate of a readout register connected to the image sensor pixel(s). For example, with reference to FIG. 2A, gate electrode 305 may perform the same function of readout register gate electrode 240.

When the signal charge is converted to a voltage by floating diffusion structure 303, such voltage may be configured to be read out via electrical connection 304, typically connected to amplifying and digitization circuits. After each pixel readout, the charge stored on floating diffusion structure 303 can be reset by reset structure 310 to prepare floating diffusion structure 303 for receiving the signal charge for the next pixel readout. Reset structure 310 includes reset gate (RG) electrode 311 and reset drain (RD) 313. Applying an appropriate voltage V_{RG} (e.g., typically a positive voltage) to reset gate electrode 311 via electrical connection 312 enables reset gate electrode 311 and connects floating diffusion structure 303 to reset drain 313, which is biased by electrical connection 314 at a voltage V_{RD} high enough for the signal charge to be drained from floating diffusion structure 303. After the signal charge is reset from floating diffusion structure 303, reset gate electrode 311 is disabled by changing the voltage V_{RG} applied by electrical connection 312, typically to a lower (more negative) value, so that the floating diffusion structure 303 is disconnected from the reset drain 313 and can receive the signal charges corresponding to the next pixel readout from the gate electrode 305.

In embodiments, the sensing node 300 is provided with a noise-cancellation gate electrode 320 which is formed atop a dielectric layer 322 and placed adjacent to floating diffusion structure 303 and partially overlapping with channel 302, as shown for example at overlap portion 323. Dielectric layer 322 may be the same dielectric layer as the other image sensor gates, or a different material and/or thickness. Noise-cancellation gate electrode 320 may be biased by electrical connection 321 to an appropriate voltage waveform V_{NC} that intentionally couples with floating diffusion structure 303 to mitigate or remove any unwanted signals that couple with floating diffusion structure 303 and therefore with the image sensor output signal, resulting in improved noise performance. These unwanted signals may be due to coupling (feedthrough) from the image sensor clocks, as described for example with reference to FIG. 1A, or from other interference.

In FIG. 3, the shape, size, placement, and configuration of noise-cancellation gate electrode 320 is simplified for illustration purposes only and in practice may include any suitable shape, size, placement, and configuration. For example, a larger size of noise-cancellation gate electrode 320 and/or a larger overlap portion 323 with channel 302 will result in larger parasitic capacitance added to the sensing node capacitance, and hence in lower sensitivity of the charge-to-voltage conversion process. On the other hand, a larger coupling capacitance between noise-cancellation gate electrode 320 and floating diffusion structure 303 will result in a more efficient removal of feedthrough from the image sensor output signal, e.g., the waveform applied to noise-cancellation gate electrode 320 may employ a smaller amplitude to cancel a given feedthrough on the image sensor output signal. Therefore, practically, a tradeoff between parameters such as the size of noise-cancellation gate electrode 320, the lateral dimensions of its overlap portion 323 with channel 302 in the region near floating diffusion structure 303, and the thickness of dielectric layer 322 may be used.

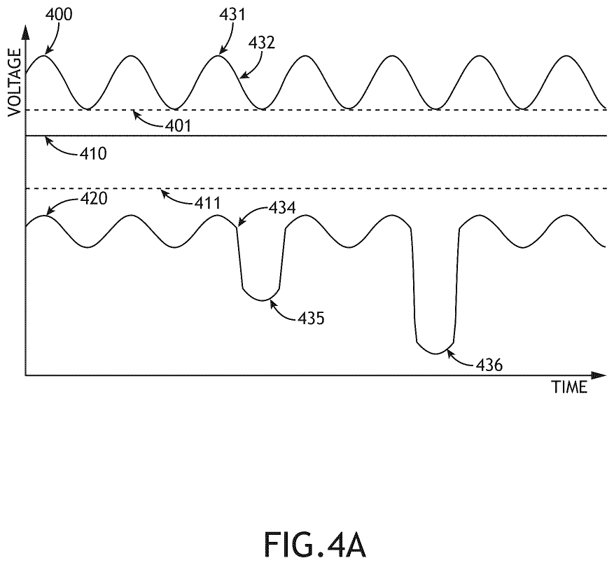

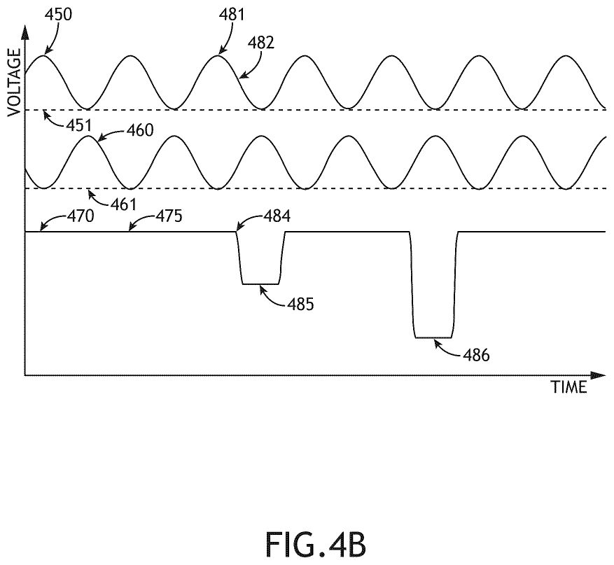

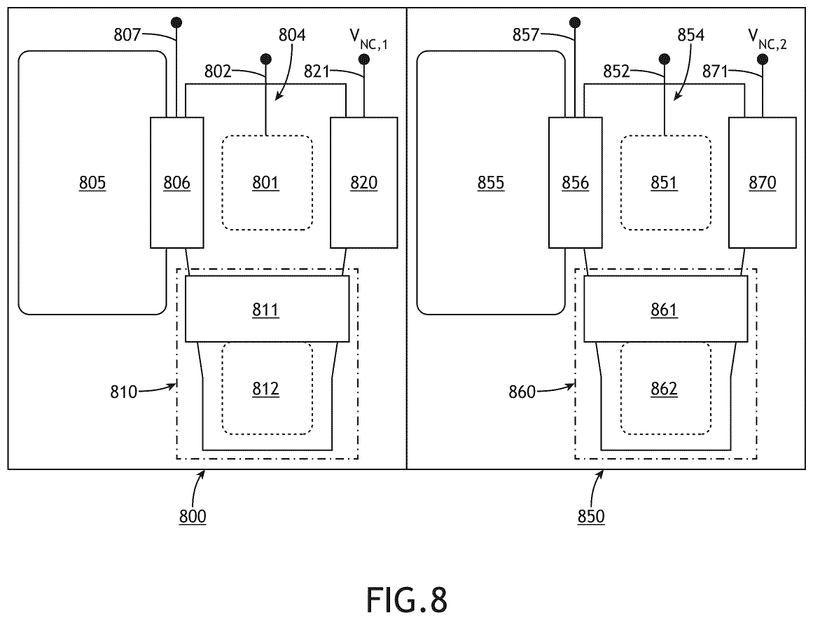

FIGS. 4A and 4B illustrate clock waveforms used to drive the reset gates and noise-cancellation gate electrodes of image sensors 200, 260 and a plurality of sensing nodes 250, 300 and output signals from such image sensors 200, 260, in accordance with one or more embodiments of the present disclosure. Examples of such gates may include those depicted in FIGS. 2A, 2B, 3, and 8, such as reset gate electrode 252 and noise-cancellation gate electrode 257 in FIGS. 2A, 2B, reset gate electrode 311 and noise-cancellation gate electrode 320 in FIG. 3, or reset gate electrodes 811, 861 and noise-cancellation gate electrodes 820, 870 in FIG. 8. Each waveform represents the voltage of a signal (such as a clock or output signal) as a function of time. The vertical axes represent voltage in arbitrary units and the horizontal axes represent time. The vertical scales of the different signals are not necessarily equal. The vertical offsets between the different signals are simplified for clarity and illustration purposes and do not imply that one voltage is more positive or more negative than another.

In FIG. 4A, waveform 400 represents the voltage of the reset clock as a function of time. This waveform 400 may represent the reset clock, which may be referred to as a reset gate voltage 400. The reset gate voltage 400 may perform the function of resetting the image sensor sensing node between consecutive pixel readouts. For example, the reset gate voltage 400 may be used to drive reset gate electrode 252 (via electrical connection 253) in FIGS. 2A, 2B or reset gate electrode 311 (via electrical connection 312) in FIG. 3. As explained above with reference to FIG. 1A and reset clock 101, in typical imaging applications the reset gate voltage 400 is pulsed using fast signal transitions, and this has consequences on the shape of the image sensor output signal (such as output signal 110 in FIG. 1A) in terms of shape, usable voltage range, and noise performance. The consequences may be severe due to the strong coupling caused by such pulsed voltage transitions on the image sensor output signal. In embodiments, the reset gate voltage 400 represents instead the voltage of a sinusoidal reset clock as a function of time. This avoids the use of fast voltage transitions, while preserving the function of resetting the image sensor sensing node between consecutive pixel readouts. When reset gate voltage 400 is larger (e.g., more positive compared to a reference voltage 401) than a certain value determined by the threshold voltage of the reset transistor, for example as shown at voltage 431, the sensing node adjacent to the reset gate and electrically connected to it will be drained of the signal charges stored on it from a previous pixel readout. When reset gate voltage 400 is then lowered below a certain value determined by the reset transistor's threshold voltage, as shown for example at voltage 432, the sensing node is reset to a floating voltage and can receive the signal charges for the next pixel readout.

Waveform 410 (e.g., the waveform of the noise-cancellation signal) represents a voltage as a function of time. For example, waveform 410 may be used to drive noise-cancellation gate electrode 257 (via electrical connection 259) in FIGS. 2A, 2B or noise-cancellation gate electrode 320 (via electrical connection 321) in FIG. 3. The noise-cancellation voltage 410 is represented as a constant voltage as a function of time, and at a more positive value than a reference voltage 411. Reference voltage 411 for noise-cancellation voltage 410 can be substantially the same as reference voltage 401 for reset gate voltage 400, or substantially different. In embodiments, such as image sensors 200, 260 in FIGS. 2A, 2B, where noise-cancellation gate electrode 257 overlaps reset gate electrode 252, driving noise-cancellation gate electrode 257 at a constant voltage (e.g., positive voltage) may be beneficial to reduce the coupling of the reset gate clock to the sensor output signal. In such a configuration, noise-cancellation gate electrode 257 acts as a capacitive shield between reset gate electrode 252 and sensing node 250, mitigating, but not completely removing, the amplitude of such coupling of the reset gate voltage to the image sensor output signal.

Waveform 420 represents the voltage of the image sensor output signal 420 as a function of time when the reset gate and the noise-cancellation gate electrode are driven by signals such as reset gate voltage 400 and noise-cancellation voltage 410, respectively, as described above. Coupling from other clocks or driving signals (not shown) necessary to read out signal charges from the image sensor pixels and/or readout registers is also possible but not shown in FIG. 4A for simplicity. In embodiments, such coupling is minimized or altogether removed by appropriately shifting the phase of such clocks so that their coupling effects to the sensor output signal 420 cancel out. In embodiments, the image sensor pixels are configured as a three-phase CCD and are driven by sinusoidal clocks that are substantially 120° shifted in phase. In embodiments, the pixel clocks could be a two-phase or four-phase clock depending on the design of the image sensor pixels.

In embodiments, the coupling of driving signals to the sensor output signal 420 is minimized by utilizing readout registers that are biased only by constant (DC) signals or near constant signals (i.e., non-pulsed signals) as described above with reference to resistive gate electrode 270 in FIG. 2B.

When only the reset gate voltage 400 and the noise-cancellation gate voltage 410 couple with the image sensor output signal 420, and in the absence of signal charges from the sensor pixels, output signal 420 will follow a smooth sinusoidal shape as shown in FIG. 4A. Compared with the strong coupling from the typically fast voltage transitions of a pulsed reset clock as illustrated in FIG. 1A, such sinusoidal coupling minimizes the disturbance of the sensor output signal 420, which will be void of high frequency noise components coming from the reset operation.

In the presence of light-induced signal charges in the image sensor pixels, such charges will be transferred to the image sensor sensing node by appropriately biasing the clock signals of the image sensor pixels and buffer gates and/or readout registers, as described above with reference to FIGS. 2A, 2B. In the example of FIG. 4A, this is accomplished by first increasing reset gate voltage 400 to a voltage level, such as voltage level 431, that connects the sensing node to an appropriate reset drain voltage that drains any pre-existing charges from the sensing node. Reset gate voltage 400 is then lowered, for example to a voltage level such as voltage level 432, so that the sensing node is disconnected from the drain voltage and new signal charges from the next pixel readout can be transferred to the sensing node. As a result of this transfer and the consequent accumulation of charges at the sensing node capacitance, output signal 420 exhibits a voltage swing proportional to the number of transferred signal charges. In the example of FIG. 4A, this happens between voltage 434, when signal charges begin to accumulate at the sensing node, and voltage 435, when all the signal charges have been collected by the sensing node. Correlated Double Sampling (CDS) may be used to measure the signal swing at the sensing node, for example by measuring the difference between voltage 434 and voltage 435. A larger number of signal charges will result in a larger voltage swing on output signal 420. For example, in FIG. 4A, voltage 436 corresponds to a larger signal charge at the sensing node compared to voltage 435.

FIG. 4B illustrates reset gate waveform 450 and noise-cancellation-gate clock waveforms 460 and a waveform 470 of a resulting voltage of the image sensor output signal 470. Waveform 450 represents the voltage of the reset clock as a function of time, waveform 460 (e.g., the waveform of the noise-cancellation signal) represents the voltage applied to the noise-cancellation gate electrode as a function of time, and waveform 470 represents the voltage of the image sensor output signal as a function of time when the reset gate and the noise-cancellation gate electrode are driven by signals such as signals 450 and 460, respectively. Similar to waveform 400 in FIG. 4A, reset gate clock 450 is a sinusoidal voltage as a function of time, to avoid the fast clock transitions of pulsed voltages and their detrimental effect on the sensor noise performance. Noise-cancellation signal waveform 460, applied to the noise-cancellation gate electrode, is also a sinusoidal voltage as a function of time, substantially shifted 180° in phase compared with waveform 450. Both waveforms 450 and 460 couple to image sensor output signal 470, however their coupling effects are also substantially shifted 180° in phase and cancel out as shown for example at portion 475 on waveform 470. In the absence of light, image sensor output signal 470 will thus be a substantially constant signal, which is very advantageous to noise performance. In embodiments, practically, the amplitude and offset of noise-cancellation signal waveform 460 (e.g., noise-cancellation gate waveform 460) may be adjusted to provide optimum cancellation of the coupling from reset clock 450 to sensor output signal 470. FIG. 4B illustrates the reference voltages 451 and 461 for reset-clock waveform 450 and noise-cancellation waveform 460, respectively. Reference voltages 451 and 461 are not necessarily the same and an offset between them is possible. In embodiments, practically, the phase shift between reset clock waveform 450 and noise-cancellation-gate waveform 460 may be adjusted to be different than 180°, depending on the total coupling from the reset gate clock and other driving signals, to ensure the most efficient coupling cancellation.

In embodiments, all image sensor driving signals are sinusoidal voltages and/or constant voltages as a function of time, all the sinusoidal voltages oscillating at the same frequency but with different phases, depending on the image sensor timing. The coupling of each such sinusoidal driving signals on the image sensor output signal may also be sinusoidal; since the sum of sinusoidal waveforms of the same frequency is also a sinusoidal waveform of that same frequency, with amplitude and phase shift determined by the amplitudes and phase shifts of the individual components, the total coupling on the image sensor output signal will be sinusoidal. Hence, driving the noise-cancellation gate with a sinusoidal voltage of appropriate amplitude and phase may ensure removal of such total coupling and be beneficial to noise performance in a similar manner to the case illustrated in FIG. 4B where the only coupling to the image sensor output signal is due to the reset gate clock.

When light-induced signal charges in the image sensor pixels are transferred to the image sensor sensing node in the presence of the noise cancellation illustrated in FIG. 4B, output signal 470 will exhibit a voltage swing proportional to the number, amount, or the like of transferred charges. In the example of FIG. 4B, this is preceded by first increasing reset gate voltage 450 to a voltage level, such as voltage level 481, that activates the reset transistor and connects the sensing node to an appropriate reset drain voltage that drains any pre-existing charges from the sensing node. Reset gate voltage 450 is then lowered to a voltage level such as voltage level 482 that deactivates the reset transistor, thus disconnecting the sensing node from the reset drain voltage, so that new signal charges can be transferred to the sensing node and produce a voltage swing on output signal 470 proportional to the number of such new signal charges. This happens between portion 484, when signal charges begin to accumulate at the sensing node, and voltage 485, when all the signal charges have been collected by the sensing node. Correlated Double Sampling (CDS) can be used to measure the voltage swing at the sensing node. For example, CDS may be used to measure the difference between portion 484 and voltage 485. A larger number of signal charges will result in a larger voltage swing on output signal 470. For example, in FIG. 4B, voltage 486 corresponds to a larger signal charge at the sensing node compared to voltage 485.

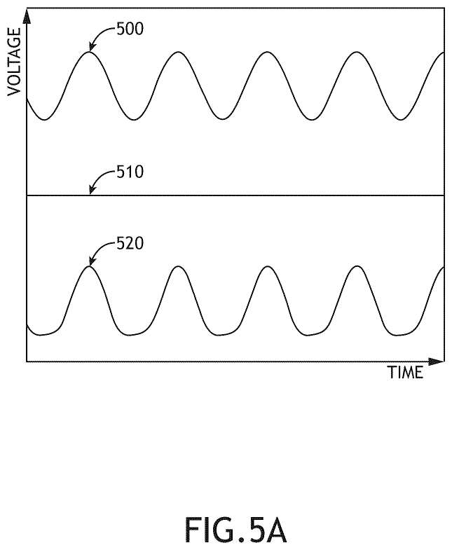

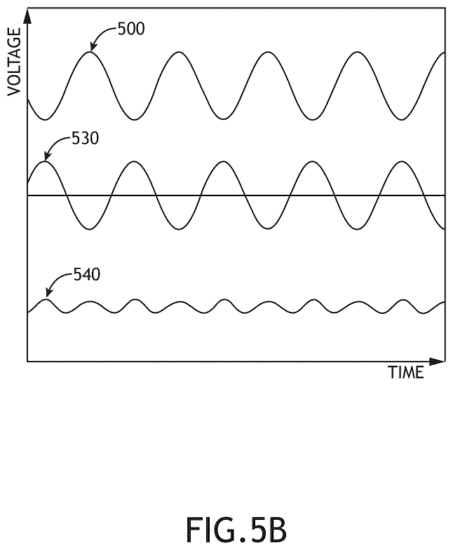

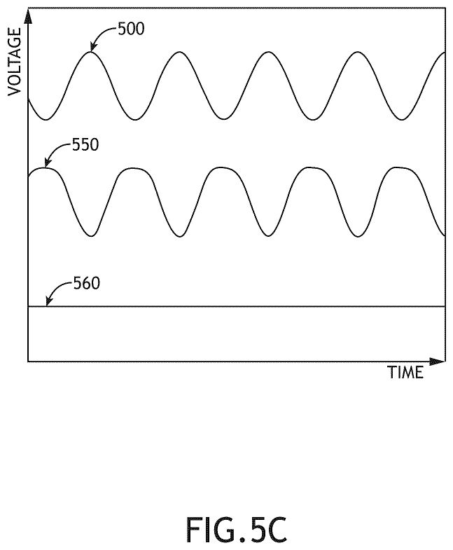

FIGS. 5A, 5B, and 5C illustrate clock waveforms used to drive the reset structures of image sensors such as those depicted in FIGS. 2A, 2B, 3, and 8 where the reset structures include both a reset gate electrode and a noise-cancellation gate electrode, and the output signals from such image sensors. For example, such a reset gate electrode and noise-cancellation gate electrode may include reset gate electrode 252 and noise-cancellation gate electrode 257, respectively, in FIGS. 2A, 2B, and reset gate electrode 311 and noise-cancellation gate electrode 320, respectively, in FIG. 3. Each waveform represents the voltage of a signal (e.g., clock or output signal) as a function of time. The vertical axes represent voltage in arbitrary units and the horizontal axes represent time. The vertical scales of the different signals are not necessarily equal. The vertical offsets between the different signals are simply for clarity and illustration purposes, are not limiting, and do not imply that one voltage is more positive or more negative than another.

Waveform 500 in each of FIGS. 5A, 5B, and 5C may be equal, such that the waveform 500 is the same reset clock waveform, represented as a sinusoidal voltage over time. In FIG. 5A, noise-cancellation signal 510 is the voltage applied to the noise-cancellation gate electrode, represented as a constant voltage, while signal 520 is the output signal 520 of the image sensor. Output signal 520 shows the feedthrough resulting from the coupling from reset clock 500. However, such feedthrough may not be ideally sinusoidal at a single frequency and may instead be distorted by higher frequency components. This could be caused by non-linearities and distortions in the driving waveform or in the capacitive coupling between the reset clock and the image sensor output signal 520. In FIG. 5B, the voltage applied to the noise-cancellation gate electrode is noise-cancellation signal 530 and is represented instead as a sinusoidal voltage at the same frequency of reset clock 500 but shifted in phase of 180°. In embodiments, in practice, as previously discussed with reference to FIGS. 4A and 4B, the amplitude of the sinusoidal voltage applied to the noise-cancellation gate electrode may need to be adjusted appropriately. In FIG. 5B, the amplitude of the waveforms is not to scale and is shown at an arbitrary scale for illustration purposes only. Voltage 540 represents the image sensor output signal when clocks 500 and 530 are applied to the reset gate electrode and the noise-cancellation gate electrode, respectively. In the presence of higher frequency feedthrough components caused by non-linearity or distortions as described above with reference to FIG. 5A with output signal 520, the feedthrough on output signal 540 is not removed completely, and a ripple due to such higher frequency feedthrough components is visible. This may not be desirable in practical applications.

In embodiments, as illustrated in FIG. 5C, voltage 550 applied to the noise-cancellation gate electrode is shaped appropriately to include the higher frequency components beyond the fundamental frequency of reset clock 500, so that the cancellation effectively removes all feedthrough from the image sensor output signal, as shown by output signal 560—which is now ideally flat in the absence of light signals.

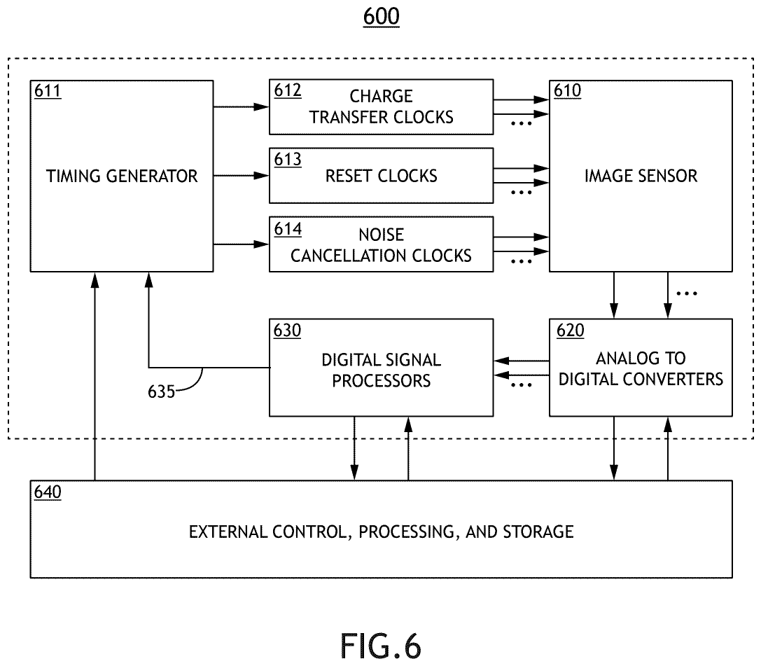

FIG. 6 illustrates an imaging apparatus 600 including an image sensor 610, a timing generator 611 for the image sensor driving clocks, analog-to-digital converters 620, digital signal processors (DSPs) 630, and an external unit 640 for image sensor control, data processing, and storage, in accordance with one or more embodiments of the present disclosure.

In embodiments, the imaging apparatus 600 includes an image sensor 610, driven by clocks generated by timing generator 611. Such clocks may include charge transfer clocks 612, reset clocks 613, and noise-cancellation clocks 614. Image sensor 610's output signal voltages are digitized by Analog-to-Digital Converters (ADCs) 620. The voltage output digitized by the ADCs 620 may be referred to as a digital number (i.e., a digitized representation of the analog voltage value). Such digital image data may be further processed by at least one Digital Signal Processor (DSP) 630. Timing generator 611, ADCs 620, and DSPs 630 are all connected to an external unit 640 for control, data processing, and storage. In embodiments, DSPs 630 analyze, receive, and/or evaluate the image sensor output signal as digitized by ADCs 620. This may include analyzing the frequency content of the image sensor output signals including their clock feedthrough, before or after noise-cancellation clocks 614 are applied to image sensor 610 to remove such clock feedthrough. Such information on the frequency content of the image sensor output signals might be output by DSPs 630, as shown for example at signal 635, and fed into timing generator 611, so that the voltage waveforms of noise-cancellation clocks 614 can be shaped appropriately to ensure removal of clock feedthrough from the image sensor output signals. For example, with reference to FIGS. 5A, 5B, and 5C, if the original image sensor output signal digitized by ADCs 620 are such as output signal 520, DSPs 630 may initially output the fundamental frequency of the clock feedthrough due to reset clock 500, and input the information into timing generator 611 that then produces a sinusoidal noise-cancellation signal of the same frequency (and with 180° phase shift), as shown by signal 530 in FIG. 5B. As a result of this noise cancellation, the image sensor output signal will now be digitized as shown by the output signal 540 in FIG. 5B, displaying residual clock feedthrough resulting from additional frequency components beyond the fundamental frequency of reset clock 500 and noise-cancellation clock 530. DSPs 630 may further analyze the image sensor output signal now digitized as output signal 540 and output the information (e.g., extracted, calculated, or the like) on such additional frequency components to timing generator 611, which will then produce a noise-cancellation clock shaped to include such additional frequency components, as shown for example by noise-cancellation signal 550 in FIG. 5C. As a result of the noise-cancellation signal 550, all clock feedthrough is removed from the image sensor output signal, as shown by output signal 560 in FIG. 5C. In embodiments, for practical purposes, the frequency analysis performed by DSPs 630 may be repeated iteratively and its results 635 fed into timing generator 611 until the optimum, feedthrough-free shape of the image sensor output signal 560 is achieved.

The timing approaches described in FIGS. 4A, 4B and 5A, 5B, 50, when applied to the plurality of sensing nodes such as described in FIGS. 2A, 2B, 3, and 8, or to an imaging apparatus 600 such as described in FIG. 6, improve on the limitations of conventional image sensors, such as described in FIG. 1A, and are beneficial to image sensors suitable for application in inspection and metrology systems. With reference to FIG. 4A, the substantially sinusoidal shape of output signal 420 minimizes the frequency content of the image sensor output signal and may essentially limit it to the single frequency of the sinusoidal reset clock. In embodiments, employing the noise-cancellation technique illustrated in FIG. 4B, the substantially constant shape of output signal 470 further minimizes the frequency content of the image sensor output to its DC (i.e., zero frequency) component and is thus ideal for noise performance since the narrow bandwidth of the image sensor output signal is now free of high-frequency noise components. In such embodiments, the complete removal, or nearly complete removal, of clock feedthrough from the image sensor output signal is also beneficial to maximize the usable sensor full well (i.e., the maximum signal that can be read out by the sensor output), since signal is not lost due to clock feedthrough. Such an image sensor can then also be read out at higher speed, given the low bandwidth required by sinusoidal clock signals. Further, driving sinusoidal clock signals may require lower power consumption compared to pulsed clock signals, which simplifies sensor and camera requirements for power management. Combined, these advantages described above may ultimately result in higher speed, lower noise image sensors, and decreased sensor and camera cost. In particular, for sensors used in a vacuum environment, such as sensors used to detect vacuum UV or extreme UV radiation, it may be difficult to efficiently remove heat from the sensor, so this reduction in heat generation may enable operation at higher speed than would otherwise be possible.

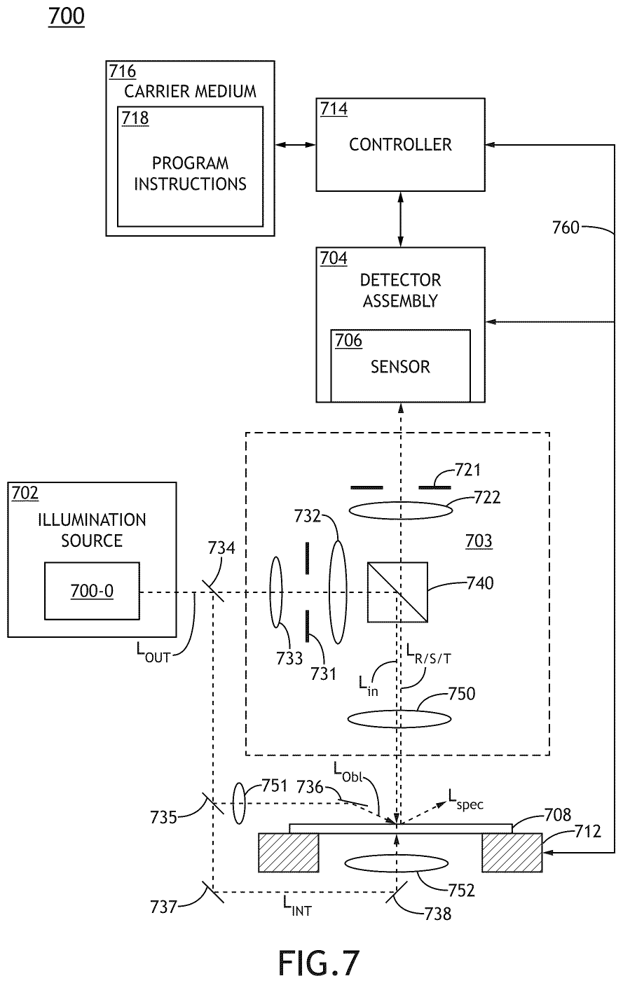

FIG. 7 illustrates a simplified block diagram of an optical system 700, in accordance with one or more embodiments of the present disclosure. FIG. 7 illustrates how image sensors of the present disclosure may be implemented in an optical system 700, for various purposes and in various configurations. The various optical elements and operating modes depicted in FIG. 7 are merely to illustrate how sensor 706 may be used in optical system 700 and are not intended to limit the scope of the present disclosure. A practical optical system 700 may implement a subset or a superset of the modes and optics depicted in FIG. 7. Additional optical elements and subsystems may be incorporated as needed for a specific application. The related references cited above, and the other references cited herein disclose many other details of systems that may incorporate the image sensor 706.

In embodiments, the optical system 700 is configured as an inspection system or a metrology system for inspecting a sample 708 and/or acquiring optical metrology measurements from the sample 708. The optical system 700 may include a semiconductor fabrication system or be coupled to transmit measurements to a semiconductor fabrication system in a feedback loop to improve the manufacture of samples based on the measurements from the optical system 700. For example, the fabrication system may be configured to cut, drill or ablate material from sample 708, or to expose a pattern onto photoresist on sample 708.

When the sample 708 is illuminated in one or more of the above-described modes, the optics 703 are also configured to collect light LR/S/T reflected, scattered, diffracted, transmitted and/or emitted from the sample 708 and direct and focus the light LR/S/T to sensor 706 of a detector assembly 704.

It is noted herein that sensor 706 and the detector assembly 704 may include any sensor 706 known in the art. The sensor 706 may include, or be, the image sensor of the present disclosure. In this way, the optical system 700 may illustrate embodiments of an image sensor 706 incorporating image sensor 200, 260 of FIGS. 2A and 2B, or any other aspect or feature of the present disclosure. For example, the sensor 706 may include, but is not limited to, a charge-coupled device (CCD) detector, a complementary metal oxide semiconductor (CMOS) detector, a time-delay integration (TDI) detector, a photomultiplier tube (PMT), an avalanche photodiode (APD), a line sensor, an electron-bombarded line sensor, or the like. The detector assembly 704 may be communicatively coupled to a controller 714 (e.g., computing system). The image sensor 706 may be positioned in a path of light from the sample 708, to image the sample 708.

The controller 714 may be configured to store and/or analyze data from detector assembly 704 under control of program instructions 718 stored on carrier medium 716. The controller 714 may be further configured to control other elements of optical system 700 such as stage 712, illumination source 702 and optics 703.

The sample 708 may include any sample known in the art such as, but not limited to, a wafer, reticle, photomask, or the like. In embodiments, the sample 708 may be disposed on a stage assembly 712 to facilitate movement of the sample 708. The stage assembly 712 may include any stage assembly known in the art including, but not limited to, an X-Y stage, an R-θ stage, and the like. In embodiments, the stage assembly 712 is capable of adjusting the height of the sample 708 during inspection to maintain focus on the sample 708. In embodiments, a lens such as objective lens 750 may be moved up and down during inspection to maintain focus on the sample 708.

In embodiments, the optical system 700 includes an illumination source 702 that incorporates a laser 700-0 that generates output light L_{OUT} having an output frequency WOUT. However, note that this is a nonlimiting example and that the illumination source 702 may include any type of illumination source suitable for providing the output light L_{OUT}. In embodiments, the illumination source 702 is a laser source. For example, the illumination source 702 may include, but is not limited to, one or more narrowband laser sources, a broadband laser source, a supercontinuum laser source, a white light laser source, or the like. In this regard, the illumination source 702 may provide an output light L_{OUT} having high coherence (e.g., high spatial coherence and/or temporal coherence). In embodiments, the illumination source 702 includes a laser-sustained plasma (LSP) source. For example, the illumination source 702 may include, but is not limited to, a LSP lamp, a LSP bulb, or a LSP chamber suitable for containing one or more elements that, when excited by a laser source into a plasma state, may emit broadband illumination.

In embodiments, the optical system 700 includes an optical sub-system configured to direct the illumination (e.g., light L_{OUT}) from the illumination source 702 onto the sample 708. For example, the optical sub-system may include any suitable elements known in the art for directing the illumination such as, but not limited to, elements 734, 733, 731, 732, 740, 750 and/or the like.

In embodiments, the optical system 700 includes one or more optical components such as, but not limited to, beam splitters, mirrors, lenses, apertures, and waveplates that are configured to condition and direct light L_{OUT} to sample 708. The optical components may be configured to illuminate an area, a line, or a spot on sample 708. In embodiments, beam splitter or mirror 734, mirrors 737 and 738, and lens 752 are configured to illuminate sample 708 from below so as to enable inspection or measurement of sample 708 by transmitting light LINT through the sample. In embodiments, beam splitters or mirrors 734 and 735, mirror 736, and lens 751 are configured to illuminate sample 708 with light at an oblique angle of incidence L_{Obl}, for example at an angle of incidence greater than 60° relative to a normal to the sample surface. In this embodiment, the specularly reflected light L_{spec} may be blocked or discarded rather than collected. In embodiments, optics 703 are collectively configured to direct illumination light LIN to the top surface of sample 708.

In embodiments, the optics 703 includes an illumination tube lens 733. The illumination tube lens 732 may be configured to image an illumination pupil aperture 731 to a pupil within an objective lens 750. For example, the illumination tube lens 732 may be configured such that the illumination pupil aperture 731 and the pupil within the objective lens 750 are conjugate to one another. In embodiments, the illumination pupil aperture 731 may be configurable by switching different apertures into the location of illumination pupil aperture 731. In embodiments, the illumination pupil aperture 731 may be configurable by adjusting a diameter or shape of the opening of the illumination pupil aperture 731. In this regard, the sample 708 may be illuminated by different ranges of angles depending on the characterization (e.g., measurement or inspection) being performed under control of the controller 714. The illumination pupil aperture 731 may also include a polarizing element to control the polarization state of the illumination light LIN.

In embodiments, the optics 703 includes a collection tube lens 722. For example, the collection tube lens 722 may be configured to image the pupil within the objective lens 750 to a collection pupil aperture 721. For instance, the collection tube lens 722 may be configured such that the collection pupil aperture 721 and the pupil within the objective lens 750 are conjugate to one another. In embodiments, the collection pupil aperture 721 may be configurable by switching different apertures into the location of collection pupil aperture 721. In embodiments, the collection pupil aperture 721 may be configurable by adjusting a diameter or shape of the opening of collection pupil aperture 721. In this regard, different ranges of angles of illumination reflected or scattered from the sample 708 may be directed to detector assembly 704 under control of the controller 714. The collection pupil aperture 721 may also include a polarizing element so that a specific polarization of light LR/S/T can be selected for transmission to sensor 706.

In embodiments, the illumination pupil aperture 731 and/or the collection pupil aperture 721 may include a programmable aperture.

The system 700 may include a controller 714 configured for determining information for the sample 708 based on output generated by an output circuit of the image sensor 706. For example, controller 714 shown in FIG. 7 may be configured in this manner. Controller 714 may be coupled to image sensor 706 in any suitable manner (e.g., via one or more transmission media, which may include “wired” and/or “wireless” transmission media) such that the controller 714 can receive the output, images, etc. generated by sensor 706. Controller 714 may be configured to perform a number of functions using the output of the sensor 706 as described herein and any other functions described further herein. This computing system may be further configured as described herein.

The controller 714 (e.g., computing system) may include one or more controllers (not shown) that are configured to perform one or more functions such as determining the information for the sample based on the output of the image sensor 706. The controller(s) of the computing system (as well as other controllers described herein) may also be referred to herein as computer system(s). Each of the computing system(s) and controller(s) or system(s) described herein may take various forms, including a personal computer system, image computer, mainframe computer system, workstation, network appliance, Internet appliance, or other device. In general, the term “computer system” may be broadly defined to encompass any device having one or more processors, which executes instructions from a memory medium. The computing system(s) and controller(s) or system(s) may also include any suitable processor known in the art such as a parallel processor. In addition, the computing system(s) and controller(s) or system(s) may include a computer platform with high-speed processing and software, either as a standalone or a networked tool.

If the system 700 includes more than one controller, then the different controllers may be coupled to each other such that images, data, information, instructions, etc. can be sent between the controllers as described further herein. For example, two or more controllers may be coupled to each other by any suitable transmission media (not shown), which may include any suitable wired and/or wireless transmission media known in the art. Two or more of such controllers may also be effectively coupled by a shared computer-readable storage medium (not shown).

The system 700 may further include connection 760 between controller 714 and detector assembly 704 and stage 712. Controller 714 may be configured to control the operation of detector assembly 704 and stage 712, and to receive relevant monitoring and/or diagnostic information from them. For example, controller 714 may generate and monitor signals necessary to bias or drive detector assembly 704, such as power supply voltages or timings and voltages of driving clocks, and signals necessary to ensure the synchronization between the movement of stage 712 and the image collection by detector assembly 704. Connection 760 may include any suitable wired and/or wireless transmission media known in the art.

The system 700 illustrated in FIG. 7 is an example for illustrative purposes only and is not meant to be limiting. Various configurations described herein may be altered to adjust the performance of the system 700 as is commonly performed by persons of the art when designing a commercial system. In addition, the systems described herein may be implemented using an existing system (e.g., by adding the image sensor embodiments and other functionality described herein to an existing system) such as systems that are commercially available from KLA Corp., Milpitas, California. For some such systems, the embodiments described herein may be provided as optional functionality of the existing system (e.g., in addition to other functionality of the system). Alternatively, the system described herein may be designed “from scratch” to provide a completely new system.

The controller 714 may be configured for determining the information in a number of different ways depending on, for example, the sample, the optical system configuration, and the information being determined for the sample. For example, in embodiments, the system is configured as an inspection system, and the information for the sample includes information for defects detected on the sample based on the output. In one such example, controller 714 may be configured for detecting defects on sample 708 by applying a defect detection method to the output generated by sensor 706. Controller 714 may be coupled to sensor 706 as described further herein so that it can receive the output generated by the sensor. Detecting defects on the sample may be performed in any suitable manner known in the art (e.g., applying a defect detection threshold to the output and determining that any output having a value above the threshold corresponds to a defect or a potential defect) with any suitable defect detection method and/or algorithm.

In another embodiment, the system is configured as a metrology system. In a further embodiment, the system is configured as a defect review system. For example, the embodiment of the system shown in FIG. 7 may be modified in one or more parameters to provide different imaging capability depending on the application for which it will be used. In one such example, the system may be configured to have a higher resolution if it is to be used for metrology rather than for inspection. In other words, the embodiment of the system shown in FIG. 7 describes some general and various configurations for a system that can be tailored in a number of manners that will be obvious to one skilled in the art to produce systems having different imaging capabilities that are more or less suitable for different applications.

In this manner, the system may be configured for generating output that is suitable for re-detecting defects on the sample in the case of a defect review system and for measuring one or more characteristics of the sample in the case of a metrology system. In a defect review system embodiment, controller 714 may be configured for re-detecting defects on sample 708 by applying a defect re-detection method to the output generated by sensor 706 and possibly determining additional information for the re-detected defects using the output generated by the sensor. In a metrology system embodiment, controller 714 may be configured for determining one or more characteristics of sample 708 using the output generated by the sensor.

Defect review typically involves re-detecting defects detected as such by an inspection process and generating additional information about the defects at a higher resolution, e.g., using the system described herein in a high magnification mode. Defect review is therefore performed at discrete locations on the sample where defects have been detected by inspection. The higher resolution data for the defects generated by defect review is generally more suitable for determining attributes of the defects such as profile, roughness, more accurate size information, etc. Controller 714 may be configured to determine such information for defects on the sample in any suitable manner known in the art.

Metrology processes are used at various steps during a semiconductor manufacturing process to monitor and control the process. Metrology processes are different than inspection processes in that, unlike inspection processes in which defects are detected on a sample, metrology processes are used to measure one or more characteristics of the sample that cannot be determined using currently used inspection tools. For example, metrology processes are used to measure one or more characteristics of a sample such as a dimension (e.g., line width, thickness, etc.) of features formed on the sample during a process such that the performance of the process can be determined from the one or more characteristics. In addition, if the one or more characteristics of the sample are unacceptable (e.g., out of a predetermined range for the characteristic(s)), the measurements of the one or more characteristics of the sample may be used to alter one or more parameters of the process such that additional samples manufactured by the process have acceptable characteristic(s).

Metrology processes are also different than defect review processes in that, unlike defect review processes in which defects that are detected by inspection are re-visited in defect review, metrology processes may be performed at locations at which no defect has been detected. In other words, unlike defect review, the locations at which a metrology process is performed on a sample may be independent of the results of an inspection process performed on the sample. In particular, the locations at which a metrology process is performed may be selected independently of inspection results. In addition, since locations on the sample at which metrology is performed may be selected independently of inspection results, unlike defect review in which the locations on the sample at which defect review is to be performed cannot be determined until the inspection results for the sample are generated and available for use, the locations at which the metrology process is performed may be determined before an inspection process has been performed on the sample. Controller 714 may be configured to determine any suitable characteristics for the sample in any suitable manner known in the art.

In any of the system embodiments described herein, controller 714 shown in FIG. 7 may be configured to generate results that include at least the information determined for the sample 708 based on the output generated by the image sensor 706 possibly with any other output generated by the controller 714. The results may have any suitable format (e.g., a KLARF file, which is a proprietary file format used by tools commercially available from KLA, a results file generated by Klarity, which is a tool that is commercially available from KLA, a lot result, etc.). In addition, all of the embodiments described herein may be configured for storing results of one or more steps of the embodiments in a computer-readable storage medium (e.g., non-transitory medium such as a hard-drive or the like). The results may include any of the results described herein and may be stored in any manner known in the art. The storage medium may include any storage medium described herein or any other suitable storage medium known in the art. After the results have been stored, the results can be accessed in the storage medium and used by any of the method or system embodiments described herein, formatted for display to a user, used by another software module, method, or system, etc. to perform one or more functions for the sample or another sample.

Such functions include, but are not limited to, altering a process such as a fabrication process or step that was or will be performed on the sample in a feedback, feedforward, in-situ manner, etc. For example, the controller may be configured to determine one or more changes to a process that was or will be performed on the sample based on the detected defect(s) and/or other determined information. The changes to the process may include any suitable changes to one or more parameters of the process. For example, if the determined information is defects detected on the sample, the controller preferably determines those changes such that the defects can be reduced or prevented on other samples on which the revised process is performed, the defects can be corrected or eliminated on the sample in another process performed on the sample, the defects can be compensated for in another process performed on the sample, etc. The controller may determine such changes in any suitable manner known in the art.

Those changes can then be sent to a semiconductor fabrication system (not shown) or a storage medium (not shown in FIG. 7) accessible to both the controller and the semiconductor fabrication system. The semiconductor fabrication system may or may not be part of the system embodiments described herein. For example, the systems described herein may be coupled to the semiconductor fabrication system, e.g., via one or more common elements such as a housing, a power supply, a sample handling device or mechanism, etc. The semiconductor fabrication system may include any semiconductor fabrication system known in the art such as a lithography tool, an etch tool, a chemical-mechanical polishing (CMP) tool, a deposition tool, and the like.

Each of the embodiments of the systems described above may be further configured according to any other embodiment(s) described herein.

Another embodiment relates to a computer-implemented method for determining information for a sample. The method includes directing light generated by an illumination source to a sample. The method also includes detecting light from the sample with an image sensor. The image sensor is configured as described further herein. For example, the light from the sample is incident on a light-sensitive area of a silicon layer of the image sensor. The method further includes determining information for the sample based on the output generated by an output circuit of the image sensor.

Each of the steps of the method may be performed as described further herein. The method may also include any other step(s) that can be performed by the system(s) described herein. The steps of the method may be performed by the systems described herein, which may be configured according to any of the embodiments described herein.

FIG. 8 illustrates a schematic diagram illustrating two image sensor pixel circuits, or pixels, each provided with a sensing node, a reset structure, and a noise-cancellation gate structure, in accordance with one or more embodiments of the present disclosure. In FIG. 8, a sensing node is provided with a reset structure and a noise-cancellation gate implemented in each pixel 800, 850. This configuration may be used in the case of embodiments in which the image sensor pixels are configured as complementary metal-oxide-semiconductor (CMOS) pixels, but a similar arrangement can be applied to other configurations as well.

In embodiments with multiple channels, the image sensor may include a first channel (such as channel 804) and a second channel (such as channel 854), with first gate electrodes (such as gate electrode 806, which may include a charge transfer gate electrode) connected to the first channel and third gate electrodes (such as gate electrode 856, which may include a charge transfer gate electrode) connected to the second channel. Similarly, the image sensor may include a first sensing node (such as sensing node 801) and a second sensing node (such as sensing node 851), a first floating diffusion structure (forming sensing node 801) and a second floating diffusion structure (forming sensing node 851), a first output circuit (connected to electrical connection 802) and a second output circuit (connected to electrical connection 852), and a first charge reset structure (such as reset structure 810) and a second charge reset structure (such as reset structure 860).

In embodiments, pixel 800 is provided with sensing node 801, which is typically a floating diffusion structure configured to perform charge-to-voltage conversion, and a reset structure 810 which may include reset gate electrode 811 and reset drain 812. Sensing node 801 and reset structure 810 may be built on the same channel 804. Pixel 850 is similarly provided with sensing node 851 and reset structure 860, including reset gate electrode 861 and reset drain 862. Sensing node 851 and reset structure 860 are built on the same channel 854. Both pixel 800 and pixel 850 include charge collection elements such as charge collection elements 805 and 855, respectively, where light-induced signal charges are collected from the image sensor substrate. For example, in a typical CMOS image sensor pixel, charge collection elements 805 and 855 are configured as photodiodes. Such signal charges can be transferred from charge collection elements 805 and 855 to the plurality of sensing nodes 801 and 851, by appropriately biasing first gate electrode 806 and third gate electrode 856, respectively, via electrical connections 807 and 857, respectively.

After each transfer of signal charges from charge collection elements 805 and 855 to sensing nodes 801 and 851, respectively, the output voltage signals corresponding to such charges can be read out via electrical connections 802 and 852, connected to sensing nodes 801 and 851, respectively. After each pixel readout, the signal charges on sensing nodes 801 and 851 are drained by operating reset structures 810 and 860, respectively, to prepare sensing nodes 801 and 851 for the transfer of charge signals for the next readout.

The driving signals for first gate electrode 806 and third gate electrode 856, and reset gate electrodes 811, 861 will capacitively couple with sensing nodes 801 and 851 and cause feedthrough and unwanted noise on the output signals of the pixels 800 and 850. To mitigate this, in embodiments, pixels 800 and 850 further include noise-cancellation gate electrodes 820 and 870, respectively, placed adjacent to sensing nodes 801 and 851, respectively, and partially overlapping with channels 804 and 854, respectively. Noise-cancellation gate electrodes 820 and 870 can be driven via electrical connections 821 and 871, respectively, with voltage waveforms V_{NC,1} and V_{NC,2} of appropriate corresponding waveforms including amplitudes and phase shifts and that intentionally couple with sensing nodes 801 and 851, respectively, so as to cancel the feedthrough from all other driving signals (e.g., charge transfer clocks and reset clocks) and improve noise performance. Voltage waveforms V_{NC,1} and V_{NC,2} can be shaped independently for each pixel, although other configurations where the same noise-cancellation voltage waveform is common to more than one pixel, or to all pixels, are also possible.

In embodiments, noise-cancellation gate electrodes 820 and 870 may partially overlap with reset gate electrodes 811 and 861, respectively, in a similar fashion as illustrated for noise-cancellation gate electrode 257 and reset gate electrode 252 in FIGS. 2A and 2B. In embodiments, for practical purposes, electrical connections 802 and 852 of sensing nodes 801 and 851, respectively, are connected to readout circuits such as amplifiers and/or Analog-to-Digital Converters (ADCs) to further process and digitize the output signals of pixels 800 and 850 and the corresponding image data. Even though such readout circuits are not shown in FIG. 8 for simplicity, they may be implemented within pixels 800 and 850, as is commonly done in CMOS image sensors for at least the first signal amplification stages, e.g., source followers, or they may be implemented on separate devices, e.g., Application-Specific Integrated Circuits (ASICs) electrically connected to the image sensor pixels.

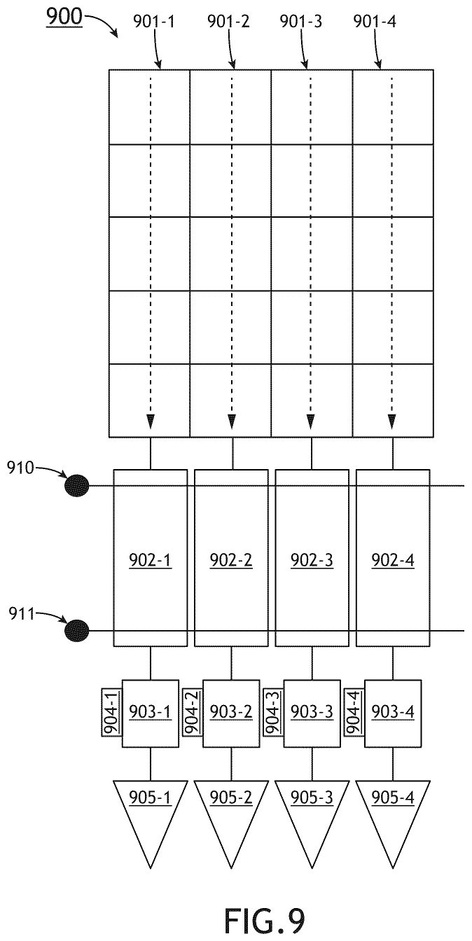

FIG. 9 illustrates a schematic diagram of an image sensor 900 in which, respectively, each resistive gate charge transfer structure 902-1, 902-2, 902-3, and 902-4 is electrically connected to a corresponding column of pixels 901-1, 901-2, 901-3, and 901-4 and to a corresponding sensing node 903-1, 903-2, 903-3, and 903-4, in accordance with one or more embodiments of the present disclosure. The resistive gate charge transfer structure 902-1, 902-2, 902-3, 902-4 may be referred to as a resistive gate, resistive gate electrode, second gate electrode, buffer gate, resistive buffer gate, and/or the like. For example, the resistive gate charge transfer structure 902-1, 902-2, 902-3, 902-4 may correspond to, be partially represented by, or the like to resistive gate electrode 270 of FIG. 2B. For example, electrode 910 may correspond to, be partially represented by, be equivalent to, or the like to electrical connection 271 of FIG. 2B.

In embodiments, the image sensor circuits are configured as a two-dimensional (2D) array of pixels. For example, in CCD image sensors suitable for semiconductor inspection systems, multiple columns of pixels such as those depicted in FIG. 2B are laid out to form a 2D array of light-sensitive pixels. Clock and driving signals are connected across the whole array and used to transfer charge from one pixel to the next within all, or a group of, columns simultaneously. However, the sensor pixels could be laid out in different configurations from those shown and may include more or fewer pixels than shown.

In other embodiments, the circuits are configured as multiple columns of pixels 901-1, 901-2, 901-3, 901-4 that include at least first and second column of pixels 901-1, 901-2, and the at least first and second columns of pixels include one or more pixels. If a column includes more than one pixel, then the first pixel is connected to the second pixel, and the second pixel is connected to the third, and so on. A resistive gate structure 902-1, 902-2, 902-3, 902-4 may be directly connected to the first pixel in each column and connected to other pixels in the same column via that one pixel. In this manner, the sensor may include a resistive gate structure for each column of pixels. More specifically, a first reset gate structure 902-1 may be electrically connected to all the pixels in only a first column of pixels 901-1, a second resistive gate structure 902-2 may be electrically connected to all the pixels in only a second column of pixels 901-2 different than the first, and so on. Each of the resistive gate structures may be configured as described herein. In this manner, the structures shown in FIG. 2B may form one column of pixels electrically connected to one resistive gate structure, and the image sensor 900 may include multiple sets of these structures arranged side by side on the image sensor 900.

A more detailed view of such an image sensor 900 is shown in FIG. 9. Image sensor 900 includes four columns of pixels 901-1, 901-2, 901-3, and 901-4. Although four columns of pixels are shown, this is a nonlimiting number and the image sensor 900 may include any number of columns such as one or more columns of pixels. In addition, although each column shown include five pixels, this is a nonlimiting number and each column may include any number of one or more pixels. For example, each column may include two or more pixels. As explained above in FIG. 2B, driving signals connected to the pixels, not shown in FIG. 9 for simplicity, may control the transfer of electrical charge along each pixel column.

As shown in FIG. 9, a first end of resistive gate electrode 902-1 is electrically connected to the first or last pixel in column 901-1 and is therefore connected to all of the pixels in that column and none of the pixels in any of the other columns. In a similar manner, the first end of resistive gate electrode 902-2 is electrically connected to all of the pixels in only column 901-2, the first end of resistive gate electrode 902-3 is electrically connected to all of the pixels in only column 901-3, and the first end of resistive gate electrode 902-4 is electrically connected to all of the pixels in only column 901-4. Each of the resistive gate structures may have the same configuration as each other resistive gate structure. The first end of each resistive gate structure receives the signal charges from the corresponding column of pixels. The signal charges are then transferred to the second end of each resistive gate structure, away from the pixels. This is accomplished by appropriately biasing the two ends of each resistive gate structure with electrodes such as 910 and 911. Electrodes 910 and 911 will typically be common to all the resistive gate structures in the sensor, as shown in FIG. 9, but other arrangements are possible. Electrode 910 biases the first end of each resistive gate structure, nearer to the corresponding column of pixels, at a voltage high enough (more positive) than the voltage applied to the last pixel in the column, so that signal charge transfers from under the last pixel in the column to under the resistive gate, in the region under electrode 910. Electrode 911, placed at the second end of each resistive gate structure, farthest from the pixels, biases the second end of each resistive gate structure at a higher voltage (more positive) than the voltage applied by electrode 910 to the first end of each resistive gate structure, so that signal charge transfers under the resistive gate from its first end, in the region under electrode 910, to its second end, in the region under electrode 911.

The second end of each resistive gate structure is electrically connected to an individual sensing node. For example, as shown in FIG. 9, sensing nodes 903-1, 903-2, 903-3, and 903-4, configured to perform charge-to-voltage conversion, are electrically connected to the second ends of resistive gate electrodes 902-1, 902-2, 902-3, and 902-4, respectively. Individual reset structures such as 904-1, 904-2, 904-3, and 904-4 are electrically connected to sensing nodes 903-1, 903-2, 903-3, and 903-4, respectively, in order to reset the signal charges between each pixel readout as explained above with reference to FIG. 2B. Further, sensing nodes 903-1, 903-2, 903-3, and 903-4 are electrically connected to individual readout circuits such as 905-1, 905-2, 905-3, and 905-4, respectively. Reset structures 904-1, 904-2, 904-3, and 904-4 may preferably each include a noise-cancellation gate electrode 257 as described above with regard to FIGS. 2A, 2B and 3. Readout circuits 905-1, 905-2, 905-3, and 905-4 typically include circuits for buffering, amplifying, digitizing, and/or processing the sensor output signals, for example as described above with reference to FIG. 2B.

With respect to the use of substantially any plural and/or singular terms herein, those having skill in the art can translate from the plural to the singular and/or from the singular to the plural as is appropriate to the context and/or application. The various singular/plural permutations are not expressly set forth herein for the sake of clarity.

The description is presented to enable one of ordinary skill in the art to make and use the disclosure as provided in the context of a particular application and its requirements. As used herein, directional terms such as “top,” “bottom,” “over,” “under,” “upper,” “upward,” “lower,” “down,” and “downward” are intended to provide relative positions for purposes of description and are not intended to designate an absolute frame of reference. Various modifications to the preferred embodiment will be apparent to those with skill in the art, and the general principles defined herein may be applied to other embodiments. Therefore, the present disclosure is not intended to be limited to the particular embodiments shown and described but is to be accorded the widest scope consistent with the principles and novel features herein disclosed.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

We claim:

1. An image sensor, comprising:
a silicon layer configured to generate electron-hole pairs based on light being incident on a light-sensitive area of the silicon layer;
a plurality of circuits formed on a first side of the silicon layer, wherein the plurality of circuits comprise at least one channel and first gate electrodes configured to control electron accumulation in the at least one channel in response to generation of the electron-hole pairs; and
a plurality of sensing nodes, wherein each of the plurality of sensing nodes is electrically connected to at least one circuit of the plurality of circuits, wherein the plurality of sensing nodes are formed on the first side of the silicon layer adjacent to the plurality of circuits, wherein each of the plurality of sensing nodes comprise:
a floating diffusion structure connected to one of the at least one channel of the plurality of circuits and an output circuit of the image sensor;
a charge reset structure configured to remove a charge from the floating diffusion structure,
wherein the floating diffusion structure is configured to convert the charge responsive to the electron accumulation to a voltage proportional to an amount of the charge and dependent on a capacitance of the floating diffusion structure,
wherein the output circuit is configured to generate output responsive to the voltage that is output by the floating diffusion structure; and
a noise-cancellation gate electrode, adjacent to the floating diffusion structure and configured to be driven by a noise-cancellation signal.

2. The image sensor of claim 1, wherein the plurality of circuits are configured as charge-coupled device (CCD) circuits.

3. The image sensor of claim 1, wherein the plurality of circuits are configured as complementary metal-oxide-semiconductor (CMOS) circuits.

4. The image sensor of claim 1, wherein the image sensor is configured as a backside illuminated charge-coupled device (CCD) sensor.

5. The image sensor of claim 1, wherein the image sensor is configured as a backside illuminated complementary metal-oxide-semiconductor (CMOS) sensor.

6. The image sensor of claim 1, wherein the image sensor is configured to function as a time-delay integration (TDI) sensor.

7. The image sensor of claim 1, wherein the image sensor is configured to function as an avalanche image sensor.

8. The image sensor of claim 1, wherein the silicon layer is a silicon epitaxial layer.

9. The image sensor of claim 1, wherein the silicon layer is a silicon epitaxial layer, and wherein the silicon layer comprises intrinsic or p-type doped silicon with a dopant concentration less than 10¹⁴ cm⁻³.

10. The image sensor of claim 1, wherein the at least one channel of the plurality of circuits comprises an n-type doped buried channel.

11. The image sensor of claim 1, wherein the silicon layer is a silicon epitaxial layer, wherein the image sensor further comprises a thin p-type layer with a dopant concentration at least ten times higher than a dopant concentration of the silicon layer, and wherein the thin p-type layer is disposed on a second side of the silicon layer opposite to the first side.

12. The image sensor of claim 1, wherein the image sensor further comprises an antireflection layer disposed on a second side of the silicon layer opposite to the first side.

13. The image sensor of claim 1, wherein the plurality of circuits are configured as a linear array of pixels.

14. The image sensor of claim 1, wherein the plurality of circuits are configured as a two-dimensional array of pixels.

15. The image sensor of claim 1, wherein each pixel comprises one or more circuits comprising the one of the at least one channel connected to the floating diffusion structure, and wherein the floating diffusion structure is configured for charge-to-voltage conversion.

16. A system configured for determining information for a sample, comprising:
an illumination subsystem configured for directing light generated by an illumination source to the sample; and
an image sensor positioned in a path of light from the sample and comprising:
a silicon layer configured to generate electron-hole pairs based on the light from the sample being incident on a light-sensitive area of the silicon layer;
a plurality of circuits formed on a first side of the silicon layer, wherein the plurality of circuits comprise at least one channel and first gate electrodes configured to control electron accumulation in the at least one channel in response to generation of the electron-hole pairs; and
a plurality of sensing nodes, wherein each of the plurality of sensing nodes is electrically connected to at least one circuit of the plurality of circuits, wherein the plurality of sensing nodes are formed on the first side of the silicon layer adjacent to the plurality of circuits, wherein each of the plurality of sensing nodes comprise:
a floating diffusion structure connected to one of the at least one channel of the plurality of circuits and an output circuit of the image sensor;
a charge reset structure configured to remove a charge from the floating diffusion structure,
wherein the floating diffusion structure is configured to convert the charge responsive to the electron accumulation to a voltage proportional to an amount of the charge and dependent on a capacitance of the floating diffusion structure,
wherein the output circuit is configured to generate output responsive to the voltage output by the floating diffusion structure;
a noise-cancellation gate electrode, adjacent to the floating diffusion structure and configured to be driven by a noise-cancellation signal;
a circuit configured to drive the noise-cancellation gate electrode with such noise-cancellation signal; and
a controller configured for determining the information for the sample based on the output.

17. The system of claim 16, wherein the system is further configured as an inspection system, and wherein the information for the sample comprises information for defects detected on the sample based on the output.

18. A method of inspecting a sample, the method comprising:
directing and focusing light onto the sample;
receiving light from the sample and directing the light to an image sensor, the image sensor comprising:
a silicon layer configured to generate electron-hole pairs based on the light from the sample being incident on a light-sensitive area of the silicon layer;
a plurality of circuits formed on a first side of the silicon layer, wherein the plurality of circuits comprise at least one channel and first gate electrodes configured to control electron accumulation in the at least one channel in response to generation of the electron-hole pairs; and
a plurality of sensing nodes, wherein each of the plurality of sensing nodes is electrically connected to at least one circuit of the plurality of circuits, wherein the plurality of sensing nodes are formed on the first side of the silicon layer adjacent to the plurality of circuits, wherein each of the plurality of sensing nodes comprise:
a floating diffusion structure connected to one of the at least one channel of the plurality of circuits and an output circuit of the image sensor;
a charge reset structure configured to remove a charge from the floating diffusion structure,
wherein the floating diffusion structure is configured to convert the charge responsive to the electron accumulation to a voltage proportional to an amount of the charge and dependent on a capacitance of the floating diffusion structure,
wherein the output circuit is configured to generate output responsive to the voltage output by the floating diffusion structure; and
a noise-cancellation gate electrode, adjacent to the floating diffusion structure and configured to be driven by a noise-cancellation signal;
moving the sample relative to the light simultaneously with the receiving;
driving the first gate electrodes with charge transfer clock signals that are synchronized to the moving of the sample relative to the light, the charge transfer clock signals causing the electron accumulation to be transferred from the first gate electrodes to the plurality of sensing nodes;
driving the charge reset structure of each sensing node with a reset clock signal that causes the electron accumulation to be removed from the floating diffusion structure of each sensing node;
driving the noise-cancellation gate electrode of each sensing node with the noise-cancellation signal; and
utilizing a readout circuit including an Analog-to-Digital Converter (ADC) coupled to the output circuit electrically connected to the floating diffusion structure of each sensing node and configured to convert the voltage output by each sensing node to a digital number.

19. The method of claim 18, the method further comprising driving the first gate electrodes with voltages following a sinusoidal waveform over time.

20. The method of claim 18, the method further comprising driving the charge reset structure of each sensing node with a voltage following a sinusoidal waveform over time.

21. The method of claim 18, wherein the noise-cancellation signal comprises a voltage following a corresponding waveform over time to cancel a feedthrough on the voltage output by each sensing node caused by one or more couplings, wherein the one or more couplings comprise a capacitive coupling of the charge transfer clock signals and the reset clock signal with each sensing node.

22. A system configured for determining information for a sample, comprising:
an illumination subsystem configured for directing light generated by an illumination source to the sample; and
an image sensor positioned in a path of light from the sample and comprising:
a silicon layer configured to generate electron-hole pairs based on the light from the sample being incident on a light-sensitive area of the silicon layer;
a plurality of circuits formed on a first side of the silicon layer, wherein the plurality of circuits comprise at least one channel and first gate electrodes configured to control electron accumulation in the at least one channel in response to generation of the electron-hole pairs; and
a plurality of sensing nodes, wherein each of the plurality of sensing nodes is electrically connected to at least one circuit of the plurality of circuits, wherein the plurality of sensing nodes are formed on the first side of the silicon layer adjacent to the plurality of circuits, wherein each of the plurality of sensing nodes comprise:
a floating diffusion structure connected to one of the at least one channel of the plurality of circuits and an output circuit of the image sensor;
a charge reset structure configured to remove a charge from the floating diffusion structure,
wherein the floating diffusion structure is configured to convert the charge responsive to the electron accumulation to a voltage proportional to an amount of the charge and dependent on a capacitance of the floating diffusion structure,
wherein the output circuit is configured to generate output responsive to the voltage output by the floating diffusion structure;
a noise-cancellation gate electrode, adjacent to the floating diffusion structure and configured to be driven by a noise-cancellation signal;
at least one Analog-to-Digital Converter (ADC) configured to generate digital image data values by digitizing corresponding voltage outputs generated on the plurality of sensing nodes;
at least one Digital Signal Processor (DSP) configured to receive and evaluate the digital image data values; and
a timing generator configured to generate charge transfer clock, reset clock, and the noise-cancellation signal utilized to drive the image sensor,
wherein the at least one DSP is configured to analyze the digital image data values to extract their frequency components and an amplitude of the frequency components,
wherein the timing generator is configured to vary each noise-cancellation signal applied to each noise-cancellation gate electrode of each of the plurality of sensing nodes based on the frequency components and the amplitude of the frequency components received by the at least one DSP, to cancel a feedthrough caused on the voltage outputs generated on the plurality of sensing nodes.

23. The system of claim 22, wherein the system is further configured as an inspection system, and wherein the information for the sample comprises information for defects detected on the sample based on the output.

24. An image sensor, comprising:
a silicon layer configured to generate electron-hole pairs when light is incident on a light-sensitive area of the silicon layer; and
a plurality of circuits formed on a first side of the silicon layer, wherein the plurality of circuits comprise:
a first channel and first gate electrodes configured to control electron accumulation in the first channel in response to generation of the electron-hole pairs;
a resistive gate electrode, formed on the first side of the silicon layer adjacent to the first gate electrodes and outside of the light-sensitive area, and formed by a resistive gate structure, wherein the resistive gate structure comprises:
a channel electrically connected to the first channel of the plurality of circuits and to a first sensing node of the image sensor; and
electrical connections configured to control a voltage in the channel of the resistive gate electrode to direct the electron accumulation from the channel of the resistive gate electrode near the first gate electrodes to the channel near the first sensing node; and
the first sensing node, formed on the first side of the silicon layer adjacent to the resistive gate electrode, wherein the first sensing node comprises:
a first floating diffusion structure connected to the first channel of the plurality of circuits and a first output circuit of the image sensor; and
a first charge reset structure configured to remove a charge from the first floating diffusion structure,
wherein the first floating diffusion structure is configured to convert the charge responsive to the electron accumulation to a voltage proportional to an amount of the charge and dependent on a capacitance of the first floating diffusion structure,
wherein the first output circuit is configured to generate output responsive to the voltage output by the first floating diffusion structure.

25. The image sensor of claim 24, wherein the image sensor is configured as a charge-coupled device.

26. The image sensor of claim 24, wherein the image sensor is configured as a backside illuminated charge-coupled device.

27. The image sensor of claim 24, wherein the image sensor is configured as a charge-coupled device further configured to function as a time-delay integration sensor.

28. The image sensor of claim 24, wherein the plurality of circuits are configured as charge-coupled device circuits.

29. The image sensor of claim 24, wherein the silicon layer is a silicon epitaxial layer.

30. The image sensor of claim 24, wherein the silicon layer is a silicon epitaxial layer, and wherein the silicon layer comprises intrinsic or p-type doped silicon with a dopant concentration less than 10¹⁴ cm⁻³.

31. The image sensor of claim 24, wherein the first channel of the plurality of circuits comprises an n-type doped buried channel.

32. The image sensor of claim 24, wherein the silicon layer is a silicon epitaxial layer, wherein the image sensor further comprises a thin p-type layer with a dopant concentration at least ten times higher than a dopant concentration of the silicon layer, and wherein the thin p-type layer is disposed on a second side of the silicon layer opposite to the first side.

33. The image sensor of claim 24, wherein the image sensor further comprises an antireflection layer disposed on a second side of the silicon layer opposite to the first side.

34. The image sensor of claim 24, wherein the first sensing node further comprises a noise-cancellation gate electrode adjacent to the first floating diffusion structure and configured to be driven by a noise-cancellation signal.

35. The image sensor of claim 24, the image sensor further comprising:
a second channel and third gate electrodes configured to control electron accumulation in the second channel in response to generation of the electron-hole pairs;
a fourth gate electrode, formed on the first side of the silicon layer adjacent to the third gate electrodes and outside of the light-sensitive area, and formed by a second resistive gate structure, wherein the second resistive gate structure comprises:
a channel electrically connected to the second channel of the plurality of circuits and to a second sensing node of the image sensor; and
electrical connections configured to control a voltage in the channel of the fourth gate electrode to direct the electron accumulation from the channel of the fourth gate electrode near the third gate electrodes to the channel near the second sensing node; and
the second sensing node, formed on the first side of the silicon layer adjacent to the fourth gate electrode, wherein the second sensing node comprises:
a second floating diffusion structure connected to the second channel of the plurality of circuits and a second output circuit of the image sensor; and
a second charge reset structure configured to remove a charge from the second floating diffusion structure,
wherein the second floating diffusion structure is configured to convert the charge responsive to the electron accumulation to a voltage proportional to an amount of the charge and dependent on a capacitance of the second floating diffusion structure,
wherein the second output circuit is configured to generate output responsive to the voltage output by the second floating diffusion structure.

36. A system configured for determining information for a sample, comprising:
an illumination subsystem configured for directing light generated by an illumination source to the sample;
an image sensor positioned in a path of light from the sample and comprising:
a silicon layer configured to generate electron-hole pairs when the light from the sample is incident on a light-sensitive area of the silicon layer; and
a plurality of circuits formed on a first side of the silicon layer, wherein the plurality of circuits comprise:
a first channel and first gate electrodes configured to control electron accumulation in the first channel in response to generation of the electron-hole pairs;
a resistive gate electrode, formed on the first side of the silicon layer adjacent to the first gate electrodes and outside of the light-sensitive area, and formed by a resistive gate structure, wherein the resistive gate structure comprises:
a channel electrically connected to the first channel of the plurality of circuits and to a first sensing node of the image sensor; and
electrical connections configured to control a voltage in the channel of the resistive gate electrode to direct the electron accumulation from the channel of the resistive gate electrode near the first gate electrodes to the channel near the first sensing node; and
the first sensing node, formed on the first side of the silicon layer adjacent to the resistive gate electrode, wherein the first sensing node comprises:
a first floating diffusion structure connected to the first channel of the plurality of circuits and a first output circuit of the image sensor; and
a first charge reset structure configured to remove a charge from the first floating diffusion structure,
wherein the first floating diffusion structure is configured to convert the charge responsive to the electron accumulation to a voltage proportional to an amount of the charge and dependent on a capacitance of the first floating diffusion structure,
wherein the first output circuit is configured to generate output responsive to the voltage output by the first floating diffusion structure; and
a controller configured for determining the information for the sample based on the output.

37. The system of claim 36, wherein the system is further configured as an inspection system, and wherein the information for the sample comprises information for defects detected on the sample based on the output.

38. The system of claim 36, wherein the image sensor further comprises:
a second channel and third gate electrodes configured to control electron accumulation in the second channel in response to generation of the electron-hole pairs;
a fourth gate electrode, formed on the first side of the silicon layer adjacent to the third gate electrodes and outside of the light-sensitive area, and formed by a second resistive gate structure, wherein the second resistive gate structure comprises:
a channel electrically connected to the second channel of the plurality of circuits and to a second sensing node of the image sensor; and
electrical connections configured to control a voltage in the channel of the fourth gate electrode to direct the electron accumulation from the channel of the fourth gate electrode near the third gate electrodes to the channel near the second sensing node; and
the second sensing node, formed on the first side of the silicon layer adjacent to the fourth gate electrode, wherein the second sensing node comprises:
a second floating diffusion structure connected to the second channel of the plurality of circuits and a second output circuit of the image sensor; and
a second charge reset structure to remove a charge from the second floating diffusion structure,
wherein the second floating diffusion structure is configured to convert the charge responsive to the electron accumulation to a voltage proportional to an amount of the charge and dependent on a capacitance of the second floating diffusion structure,
wherein the second output circuit is configured to generate output responsive to the voltage output by the second floating diffusion structure.

39. The system of claim 36, wherein the first sensing node further comprises a noise-cancellation gate electrode adjacent to the first floating diffusion structure and configured to be driven by a noise-cancellation signal.

40. A method of inspecting a sample, the method comprising:
directing and focusing light onto the sample;
receiving light from the sample and directing received light to an image sensor, the image sensor comprising:
a silicon layer configured to generate electron-hole pairs when the light from the sample is incident on a light-sensitive area of the silicon layer; and
a plurality of circuits formed on a first side of the silicon layer, wherein the plurality of circuits comprise:
a first channel and first gate electrodes configured to control electron accumulation in the first channel in response to generation of the electron-hole pairs;
a resistive gate electrode, formed on the first side of the silicon layer adjacent to the first gate electrodes and outside of the light-sensitive area, and formed by a resistive gate structure, wherein the resistive gate structure comprises:
a channel electrically connected to the first channel of the first gate electrodes and to a first sensing node of the image sensor; and
electrical connections configured to control a voltage in the channel of the resistive gate electrode to direct the electron accumulation from the channel of the resistive gate electrode near the first gate electrodes to the channel near the first sensing node; and
the first sensing node, formed on the first side of the silicon layer adjacent to the resistive gate electrode, wherein the first sensing node comprises:
a first floating diffusion structure connected to the first channel of the plurality of circuits and a first output circuit of the image sensor; and
a first charge reset structure configured to remove a charge from the first floating diffusion structure,
wherein the first floating diffusion structure is configured to convert the charge responsive to the electron accumulation to a voltage proportional to an amount of the charge and dependent on a capacitance of the first floating diffusion structure,
wherein the first output circuit is configured to generate output responsive to the voltage output by the first floating diffusion structure;
moving the sample relative to the light simultaneously with the receiving;
driving the first gate electrodes with charge transfer clock signals that are synchronized to the moving of the sample relative to the light, the charge transfer clock signals causing the electron accumulation to be transferred from one of the first gate electrodes to an adjacent first gate electrode and to the resistive gate electrode electrically connected to the first gate electrodes;
driving the resistive gate electrode with constant voltages, wherein the resistive gate electrode is provided with a more positive voltage near the first sensing node compared to near the first gate electrodes, the constant voltages causing the electron accumulation to be transferred from the channel of the resistive gate electrode near the first gate electrodes to the channel near the first sensing node, and to the first sensing node adjacent to the resistive gate electrode; and
utilizing a first readout circuit including an analog-to-digital converter (ADC) coupled to the first output circuit electrically connected to the first sensing node and configured to convert the voltage output by the first sensing node to a digital number.

41. The method of claim 40, wherein the first sensing node further comprises a noise-cancellation gate electrode adjacent to the first floating diffusion structure and configured to be driven by a noise-cancellation signal.

42. The method of claim 40, wherein the image sensor further comprises:
a second channel and third gate electrodes configured to control electron accumulation in the second channel in response to generation of the electron-hole pairs;
a fourth gate electrode, formed on the first side of the silicon layer adjacent to the third gate electrodes and outside of the light-sensitive area, and formed by a second resistive gate structure, wherein the second resistive gate structure comprises:
a channel electrically connected to the second channel of the third gate electrodes and to a second sensing node of the image sensor; and
electrical connections configured to control a voltage in the channel of the fourth gate electrode to direct the electron accumulation from the channel of the fourth gate electrode near the third gate electrodes to the channel near the second sensing node; and
the second sensing node, formed on the first side of the silicon layer adjacent to the fourth gate electrode, wherein the second sensing node comprises:
a second floating diffusion structure connected to the second channel of the plurality of circuits and a second output circuit of the image sensor; and
a second charge reset structure configured to remove a charge from the second floating diffusion structure,
wherein the second floating diffusion structure is configured to convert the charge responsive to the electron accumulation to a voltage proportional to an amount of the charge and dependent on a capacitance of the second floating diffusion structure,
wherein the second output circuit is configured to generate output responsive to the voltage output by the second floating diffusion structure,
and wherein the method further comprises:
driving the third gate electrodes with charge transfer clock signals that are synchronized to the moving of the sample relative to the light, the charge transfer clock signals causing the electron accumulation to be transferred from one of the third gate electrodes to an adjacent third gate electrode and to the fourth gate electrode electrically connected to the third gate electrodes; and
driving the fourth gate electrode with constant voltages, wherein the fourth gate electrode is provided with a more positive voltage near the second sensing node compared to near the third gate electrodes, the constant voltages causing the electron accumulation to be transferred from the channel of the fourth gate electrode near the third gate electrodes to the channel near the second sensing node, and to the second sensing node adjacent to the fourth gate electrode.

43. The method of claim 42, the method further comprising utilizing a second readout circuit including a second ADC coupled to the second output circuit electrically connected to the second sensing node and configured to convert the voltage output by the second sensing node to a digital number.

44. The method of claim 42, the method further comprising driving the first gate electrodes with a sinusoidal waveform.

45. The method of claim 42, the method further comprising driving the first charge reset structure of the first sensing node with a voltage following a sinusoidal waveform over time.

46. The method of claim 42, the method further comprising driving the third gate electrodes with same sinusoidal waveform as the first gate electrodes.

47. The method of claim 42, the method further comprising driving the fourth gate electrode with same constant voltages as the resistive gate electrode.

48. The method of claim 42, the method further comprising driving the second charge reset structure with same sinusoidal waveform as the first charge reset structure.

49. The method of claim 48, wherein the second sensing node further comprises a noise-cancellation gate electrode adjacent to the second floating diffusion structure and configured to be driven by a second noise-cancellation signal.

50. A system configured for determining information for a sample, comprising:
an illumination subsystem configured for directing light generated by an illumination source to the sample; and
an image sensor positioned in a path of light from the sample and comprising:
a silicon layer configured to generate electron-hole pairs based on the light from the sample being incident on a light-sensitive area of the silicon layer;
a plurality of circuits formed on a first side of the silicon layer, wherein the plurality of circuits comprise at least one channel and first gate electrodes configured to control electron accumulation in the at least one channel in response to generation of the electron-hole pairs; and
a plurality of sensing nodes, wherein each of the plurality of sensing nodes is electrically connected to at least one circuit of the plurality of circuits, formed on the first side of the silicon layer adjacent to the plurality of circuits, wherein each of the plurality of sensing nodes comprise:
a floating diffusion structure connected to one of the at least one channel of the plurality of circuits and an output circuit of the image sensor;
a charge reset structure configured to remove a charge from the floating diffusion structure,
wherein the floating diffusion structure is configured to convert the charge responsive to the electron accumulation to a voltage proportional to an amount of the charge and dependent on a capacitance of the floating diffusion structure,
wherein the output circuit is configured to generate output responsive to the voltage output by the floating diffusion structure;
a timing generator configured to drive the charge reset structure with a sinusoidal reset clock signal; and
a controller configured for determining the information for the sample based on the output.

51. The system of claim 50, wherein the system is further configured as an inspection system, and wherein the information for the sample comprises information for defects detected on the sample based on the output.

52. A method of inspecting a sample, the method comprising:
directing and focusing light onto the sample;
receiving light from the sample and directing the light to an image sensor, the image sensor comprising:
a silicon layer configured to generate electron-hole pairs based on the light from the sample being incident on a light-sensitive area of the silicon layer;
a plurality of circuits formed on a first side of the silicon layer, wherein the plurality of circuits comprise at least one channel and first gate electrodes configured to control electron accumulation in the at least one channel in response to generation of the electron-hole pairs; and
a plurality of sensing nodes, wherein each of the plurality of sensing nodes is electrically connected to at least one circuit of the plurality of circuits, formed on the first side of the silicon layer adjacent to the plurality of circuits, wherein each of the plurality of sensing nodes comprise:
a floating diffusion structure connected to one of the at least one channel of the plurality of circuits and an output circuit of the image sensor; and
a charge reset structure configured to remove a charge from the floating diffusion structure,
wherein the floating diffusion structure is configured to convert the charge responsive to the electron accumulation to a voltage proportional to an amount of the charge and dependent on a capacitance of the floating diffusion structure,
wherein the output circuit is configured to generate output responsive to the voltage output by the floating diffusion structure;
moving the sample relative to the light simultaneously with the receiving;
driving the first gate electrodes with charge transfer clock signals that are synchronized to the moving of the sample relative to the light, the charge transfer clock signals causing the electron accumulation to be transferred from the first gate electrodes to the plurality of sensing nodes;
driving the charge reset structure of each sensing node with a reset clock signal that causes the electron accumulation to be removed from the floating diffusion structure of each sensing node,
wherein the reset clock signal comprises a sinusoidal reset clock signal; and
utilizing a readout circuit including an Analog-to-Digital Converter (ADC) coupled to the output circuit electrically connected to the floating diffusion structure of each sensing node and configured to convert the voltage output by each sensing node to a digital number.

53. The method of claim 52, the method further comprising driving the first gate electrodes with voltages following a sinusoidal waveform over time.
